(19) United States
(12) Patent Application Publication
(10) Pub. No.: US 2026/0324254 A1
(43) Pub. Date: Oct. 15, 2026

(54) MOTHER SUBSTRATE AND DISPLAY DEVICE

(71) Applicant: Magnolia White Corporation, Tokyo (JP)

(72) Inventors: Ryota TAKASAKI, Tokyo (JP); Sho YANAGISAWA, Tokyo (JP)

(73) Assignee: Magnolia White Corporation, Tokyo (JP)

(21) Appl. No.: 19/641,558

(22) Filed: Apr. 8, 2026

(30) Foreign Application Priority Data
Apr. 15, 2025 (JP) 2025-066860

(51) Int. Cl. H10K 59/80; H10K 59/12; H10K 59/122

(52) U.S. Cl. CPC H10K 59/871; H10K 59/1201; H10K 59/122

(57) ABSTRACT

According to one embodiment, a mother substrate includes an organic insulating layer provided across a display area and a surrounding area, an inorganic insulating layer on the organic insulating layer, a lower electrode, a stacked film including an organic layer and an upper electrode, a partition provided on the inorganic insulating layer in the display area and formed in an overhang shape, a first sealing layer provided on the stacked film in the display area, a first resin layer provided above the first sealing layer, a second sealing layer provided on the first resin layer and provided in the surrounding area, and a surrounding partition provided between the inorganic insulating layer and the second sealing layer in the surrounding area and formed in an overhang shape.

### CROSS-REFERENCE TO RELATED APPLICATION

This application is based upon and claims the benefit of priority from Japanese Patent Application No. 2025-066860, filed Apr. 15, 2025, the entire contents of which are incorporated herein by reference.

### FIELD

Embodiments described herein relate generally to a mother substrate and a display device.

### BACKGROUND

Recently, display devices with organic light-emitting diodes (OLED) applied thereto as display elements have been put into practical use. Each of these display elements comprises a pixel circuit including a thin-film transistor, a lower electrode connected to the pixel circuit, an organic layer covering the lower electrode, and an upper electrode covering the organic layer. The organic layer includes functional layers such as a hole transport layer and an electron transport layer in addition to a light emitting layer.

This type of display device demands a technique for suppressing increases in manufacturing cost.

### BRIEF DESCRIPTION OF THE DRAWINGS

FIG. 1 is a view showing a configuration example of a display device DSP.

FIG. 2 is a diagram showing an example of the layout of subpixels SP1, SP2, and SP3 which constitute one pixel PX.

FIG. 3 is a schematic cross-sectional view of a display panel PNL along the A-B line of FIG. 2.

FIG. 4 is a schematic cross-sectional view of the display panel PNL along the C-D line of FIG. 1.

FIG. 5A is a view for describing a manufacturing method of the display device.

FIG. 5B is a view for describing the manufacturing method of the display device.

FIG. 5C is a view for describing the manufacturing method of the display device.

FIG. 5D is a view for describing the manufacturing method of the display device.

FIG. 5E is a view for describing the manufacturing method of the display device.

FIG. 5F is a view for describing the manufacturing method of the display device.

FIG. 5G is a view for describing the manufacturing method of the display device.

FIG. 5H is a view for describing the manufacturing method of the display device.

FIG. 6 is a schematic plan view showing part of a mother substrate 100.

FIG. 7A is a schematic cross-sectional view showing a configuration example of the mother substrate 100 in the vicinity of a cutting line CL shown in FIG. 6.

FIG. 7B is a schematic cross-sectional view showing an outermost peripheral portion PP of the display panel PNL separated along the cutting line CL shown in FIG. 7A.

FIG. 8A is a schematic cross-sectional view showing another configuration example of the mother substrate 100 in the vicinity of the cutting line CL.

FIG. 8B is a schematic cross-sectional view showing the outermost peripheral portion PP of the display panel PNL separated along the cutting line CL shown in FIG. 8A.

FIG. 9A is a schematic cross-sectional view showing another configuration example of the mother substrate 100 in the vicinity of the cutting line CL.

FIG. 9B is a schematic cross-sectional view showing the outermost peripheral portion PP of the display panel PNL separated along the cutting line CL shown in FIG. 9A.

FIG. 10A is a schematic cross-sectional view showing another configuration example of the mother substrate 100 in the vicinity of the cutting line CL.

FIG. 10B is a schematic cross-sectional view showing the outermost peripheral portion PP of the display panel PNL separated along the cutting line CL shown in FIG. 10A.

FIG. 11 is a schematic cross-sectional view of another configuration example of the display panel PNL along the C-D line of FIG. 1.

FIG. 12A is a schematic cross-sectional view showing a configuration example of the mother substrate 100 in the vicinity of a cutting line CL shown in FIG. 6.

FIG. 12B is a schematic cross-sectional view showing the outermost peripheral portion PP of the display panel PNL separated along the cutting line CL shown in FIG. 12A.

FIG. 13A is a schematic cross-sectional view showing another configuration example of the mother substrate 100 in the vicinity of the cutting line CL.

FIG. 13B is a schematic cross-sectional view showing the outermost peripheral portion PP of the display panel PNL separated along the cutting line CL shown in FIG. 13A.

FIG. 14A is a schematic cross-sectional view showing another configuration example of the mother substrate 100 in the vicinity of the cutting line CL.

FIG. 14B is a schematic cross-sectional view showing the outermost peripheral portion PP of the display panel PNL separated along the cutting line CL shown in FIG. 14A.

FIG. 15A is a schematic cross-sectional view showing another configuration example of the mother substrate 100 in the vicinity of the cutting line CL.

FIG. 15B is a schematic cross-sectional view showing the outermost peripheral portion PP of the display panel PNL separated along the cutting line CL shown in FIG. 15A.

FIG. 16A is a plan view showing an example of the layout of surrounding partitions 7.

FIG. 16B is a plan view showing another example of the layout of the surrounding partitions 7.

FIG. 16C is a plan view showing another example of the layout of the surrounding partitions 7.

FIG. 16D is a plan view showing another example of the layout of the surrounding partitions 7.

FIG. 16E is a plan view showing another example of the layout of the surrounding partitions 7.

FIG. 16F is a plan view showing another example of the layout of the surrounding partitions 7.

FIG. 16G is a plan view showing another example of the layout of the surrounding partitions 7.

FIG. 16H is a plan view showing another example of the layout of the surrounding partitions 7.

FIG. 16I is a plan view showing another example of the layout of the surrounding partitions 7.

FIG. 16J is a plan view showing another example of the layout of the surrounding partitions 7.

### DETAILED DESCRIPTION

An object of embodiments is to provide a mother substrate and a display device each capable of suppressing an increase in manufacturing cost.

In general, according to one embodiment, a mother substrate includes a substrate, an organic insulating layer provided across a display area configured to display an image and a surrounding area outside the display area, an inorganic insulating layer provided on the organic insulating layer across the display area and the surrounding area, a lower electrode provided on the organic insulating layer in the display area and having a peripheral portion covered by the inorganic insulating layer, a stacked film provided on the lower electrode and including an upper electrode and an organic layer including a light-emitting layer, a partition provided on the inorganic insulating layer in the display area, having conductivity, contacting the upper electrode, and formed in an overhang shape, a first sealing layer formed of an inorganic insulating material and provided on the stacked film in the display area, a first resin layer provided above the first sealing layer in the display area, a second sealing layer formed of an inorganic insulating material, provided on the first resin layer in the display area, and provided in the surrounding area, and a surrounding partition provided between the inorganic insulating layer and the second sealing layer in the surrounding area and formed in an overhang shape.

According to another embodiment, a display device includes a substrate having a substrate edge, an organic insulating layer provided above the substrate across a display area configured to display an image and a surrounding area outside the display area and having an end portion directly above the substrate edge, an inorganic insulating layer provided on the organic insulating layer across the display area and the surrounding area, a lower electrode provided on the organic insulating layer in the display area and having a peripheral portion covered by the inorganic insulating layer, a stacked film provided on the lower electrode and including an upper electrode and an organic layer including a light-emitting layer, a partition provided on the inorganic insulating layer in the display area, having conductivity, contacting the upper electrode, and formed in an overhang shape, a first sealing layer formed of an inorganic insulating material and provided on the stacked film in the display area, a first resin layer provided above the first sealing layer in the display area and having an end portion between the substrate edge and the display area, a second sealing layer formed of an inorganic insulating material, provided on the first resin layer in the display area, and provided in the surrounding area, and a surrounding partition provided between the inorganic insulating layer and the second sealing layer in the surrounding area and formed in an overhang shape.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc. of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as a first direction X. A direction parallel to the Y-axis is referred to as a second direction Y. A direction parallel to the Z-axis is referred to as a third direction Z. A plan view is defined as appearance when various types of elements are viewed parallel to the third direction Z. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as an upward direction or a direction to an upper side.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

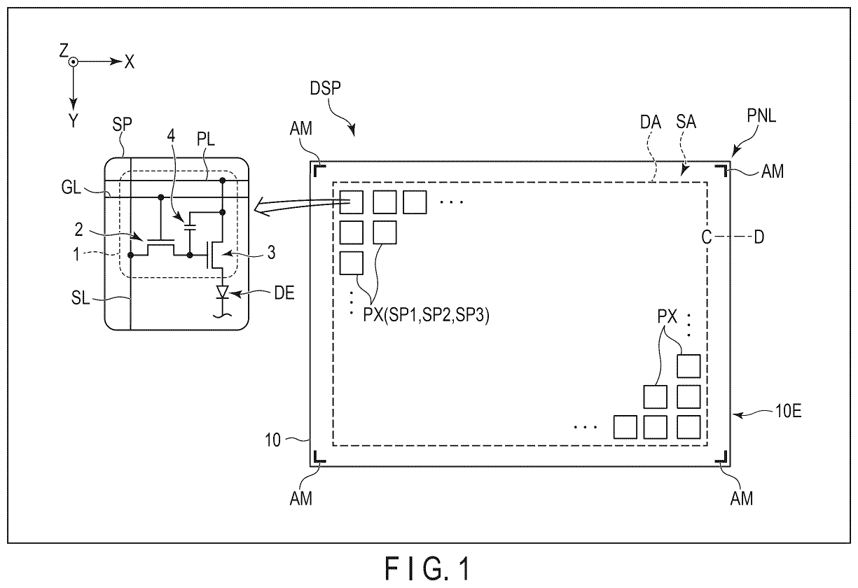

FIG. 1 is a view showing a configuration example of a display device DSP.

The display device DSP comprises a display panel PNL. The display panel PNL has a display area DA for displaying images and a surrounding area SA around the display area DA on an insulating substrate 10. The substrate 10 may be either a glass substrate or a resinous substrate having flexibility.

In the illustrated example, the substrate 10 has a substrate edge 10E formed in a rectangular shape in plan view. An alignment mark AM is provided in the surrounding area SA between the substrate edge 10E and the display area DA. The alignment mark AM is shaped, for example, in a L shape and is located at the corner of the substrate 10. The shape of the alignment mark AM is not limited to the shown example. The shape of the substrate edge 10E in plan view is not limited to the shown example and may be another shape such as a square shape, a circular shape, or an elliptic shape. Alternatively, the substrate edge 10E may have a shape corresponding to the combination of a straight portion and a round portion.

The display area DA comprises a plurality of pixels PX arranged in a matrix in the first direction X and the second direction Y. Each pixel PX includes a plurality of subpixels SP that display different colors. For example, each pixel PX includes three subpixels SP: a subpixel SP1 which displays the first color; a subpixel SP2 which displays the second color; and a subpixel SP3 which displays the third color. The first color, the second color, and the third color are mutually different colors. Each pixel PX may include a subpixel SP, which displays another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to the scanning line GL. One of a source electrode and a drain electrode of the pixel switch 2 is connected to a signal line SL. The other is connected to a gate electrode of the drive transistor 3 and the capacitor 4. In the drive transistor 3, one of a source electrode and a drain electrode is connected to a power line PL and the capacitor 4. The other is connected to an anode of the display element DE. In the illustrated example, the scanning line GL and the power line PL extend in the first direction X and the signal line SL extends in the second direction Y.

The configuration of the pixel circuit 1 is not limited to the illustrated example. For example, the pixel circuit 1 may comprise more thin-film transistors and capacitors.

For example, the display element DE is an organic light emitting diode (OLED) as a light emitting element and thus may be called an organic EL element.

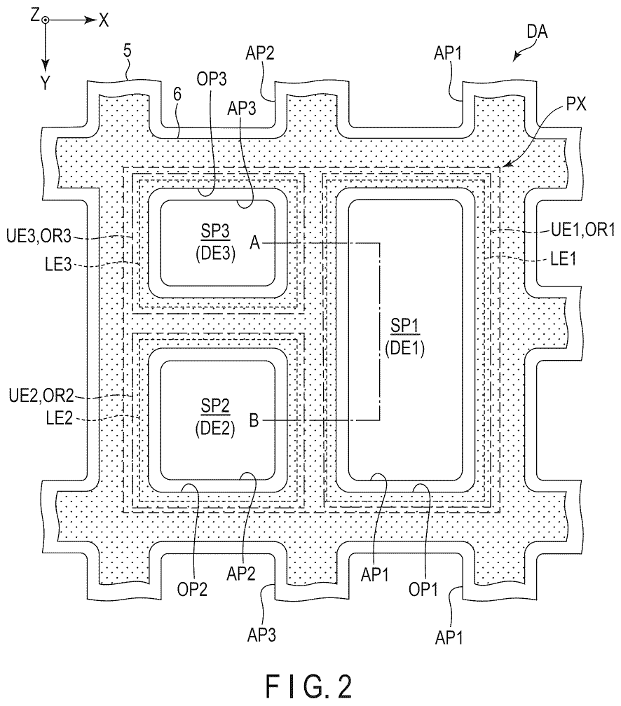

FIG. 2 is a diagram showing an example of the layout of the subpixels SP1, SP2, and SP3 which constitute the pixel PX.

In the illustrated example, in the pixel PX, the subpixel SP1 extends in the second direction Y, the subpixels SP2 and SP3 are arranged in the second direction Y. Further, the subpixels SP1 and SP2 are arranged in the first direction X, and the subpixels SP1 and SP3 are arranged in the first direction X.

When the subpixels SP1, SP2, and SP3 are arranged in this layout, in the display area DA, a column in which the subpixels SP2 and SP3 are alternately arranged in the second direction Y and a column in which the plurality of subpixels SP1 are arranged in the second direction Y are formed. These columns are alternately arranged in the first direction X. The layout of the subpixels SP1, SP2, and SP3 is not limited to the illustrated example.

An inorganic insulating layer 5 and a partition 6 are provided in the display area DA. The inorganic insulating layer 5 has apertures AP1, AP2, and AP3 in the respective subpixels SP1, SP2, and SP3. The inorganic insulating layer 5 having these apertures AP1, AP2, and AP3 may be called a rib.

The partition 6 overlaps the inorganic insulating layer 5 in plan view. The partition 6 has respective apertures OP1, OP2, and OP3 in the respective subpixels SP1, SP2, and SP3 in the same manner as the inorganic insulating layer 5. That is, the inorganic insulating layer 5 and the partition 6 each are formed in a lattice shape. The aperture OP1 overlaps the aperture AP1. The aperture OP2 overlaps the aperture AP2. The aperture OP3 overlaps the aperture AP3. The partition 6 is conductive and is electrically connected to a terminal with common voltage in the surrounding area SA shown in FIG. 1.

The subpixels SP1, SP2, and SP3 comprise respective display elements DE1, DE2, and DE3 as the display elements DE.

The display element DE1 of the subpixel SP1 comprises a lower electrode LE1, an upper electrode UE1, and an organic layer OR1, which overlap the aperture AP1. The peripheral portion of the lower electrode LE1 is covered by the inorganic insulating layer 5. The lower electrode LE1, the organic layer OR1, and the upper electrode UE1, which constitute the display element DE1 are surrounded by the partition 6 in plan view. The peripheral portion of each of the organic layer OR1 and the upper electrode UE1 overlaps the inorganic insulating layer 5 in plan view.

The display element DE2 of the subpixel SP2 comprises a lower electrode LE2, an upper electrode UE2, and an organic layer OR2, which overlap the aperture AP2. The peripheral portion of the lower electrode LE2 is covered by the inorganic insulating layer 5. The lower electrode LE2, the organic layer OR2, and the upper electrode UE2, which constitute the display element DE2 are surrounded by the partition 6 in plan view. The peripheral portion of each of the organic layer OR2 and the upper electrode UE2 overlaps the inorganic insulating layer 5 in plan view.

The display element DE3 of the subpixel SP3 comprises a lower electrode LE3, an upper electrode UE3, and an organic layer OR3, which overlap the aperture AP3. The peripheral portion of the lower electrode LE3 is covered by the inorganic insulating layer 5. The lower electrode LE3, the organic layer OR3, and the upper electrode UE3, which constitute the display element DE3 are surrounded by the partition 6 in plan view. The peripheral portion of each of the organic layer OR3 and the upper electrode UE3 overlaps the inorganic insulating layer 5 in plan view.

In the illustrated example, the outlines of the lower electrodes LE1, LE2, and LE3 are indicated by dotted lines, and the outlines of the organic layers OR1, OR2, and OR3 and the upper electrodes UE1, UE2, and UE3 are indicated by short dashed lines. The outlines of the respective lower electrodes, organic layers, and upper electrodes shown in the figure may not reflect the exact shapes.

For example, the lower electrodes LE1, LE2, and LE3 correspond to the anodes of the display elements. The upper electrodes UE1, UE2, and UE3 correspond to the cathodes of the display elements or a common electrode and contact the partition 6.

The lower electrode LE1 is electrically connected to the pixel circuit 1 (refer to FIG. 1) of the subpixel SP1. The lower electrode LE2 is electrically connected to the pixel circuit 1 of the subpixel SP2. The lower electrode LE3 is electrically connected to the pixel circuit 1 of the subpixel SP3.

In the illustrated example, the planar size of the aperture AP1, the planar size of the aperture AP2, and the planar size of the aperture AP3 differ from each other. The planar size of the aperture AP1 is greater than the aperture AP2. The planar size of the aperture AP2 is greater than the aperture AP3. The magnitude relationship of the planar sizes of the apertures AP1, AP2, and AP3 is not limited to the illustrated example.

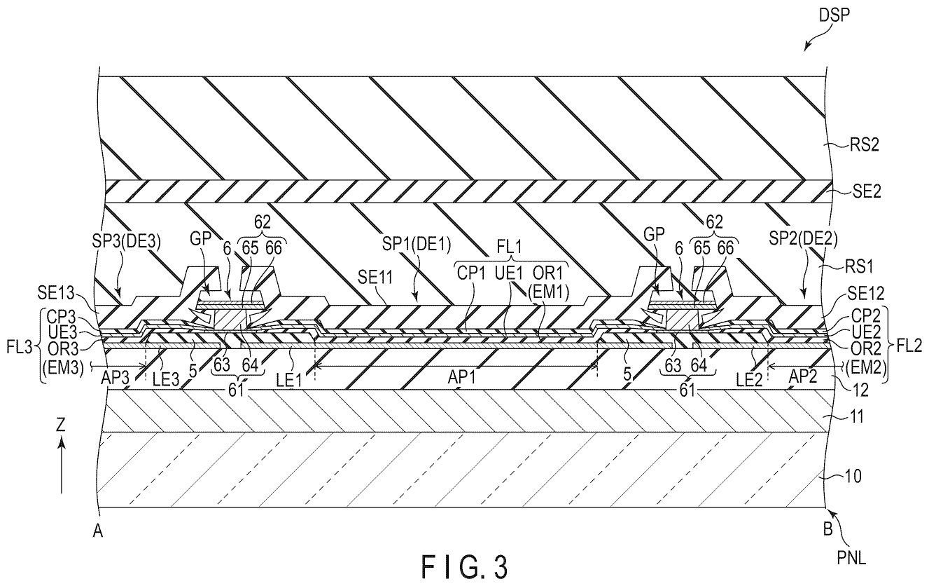

FIG. 3 is a schematic cross-sectional view of the display panel PNL along the A-B line of FIG. 2.

A circuit layer 11 is provided on the substrate 10. The circuit layer 11 includes various circuits such as the pixel circuits 1 shown in FIG. 1, various lines such as the scanning line GL, the signal line SL, and the power line PL, and various insulating layers.

An organic insulating layer 12 is provided on the circuit layer 11. For example, the organic insulating layer 12 is formed to planarize irregularities formed by the circuit layer 11.

The lower electrode LE1 of the subpixel SP1, the lower electrode LE2 of the subpixel SP2, and the lower electrode LE3 of the subpixel SP3 are provided on the organic insulating layer 12 and are spaced apart from each other.

The inorganic insulating layer 5 is provided on the organic insulating layer 12 and the lower electrodes LE1, LE2, and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2, and LE3 are covered by the inorganic insulating layer 5. The lower electrodes LE1, LE2, and LE3 are connected to the pixel circuits 1 of the respective subpixels SP1, SP2, and SP3 through the contact holes provided in the organic insulating layer 12. The illustration of the contact holes in the organic insulating layer 12 is omitted.

The partition 6 is formed in an overhang shape and comprises a lower portion 61 having conductivity and provided on the inorganic insulating layer 5 and an upper portion 62 provided on the lower portion 61.

In the illustrated example, the lower portion 61 comprises a bottom layer 63 provided on the inorganic insulating layer 5 and a stem layer 64 provided between the bottom layer 63 and the upper portion 62. The bottom layer 63 is thinner than the stem layer 64. The bottom layer 63 has the width greater than the stem layer 64. Both end portions of the bottom layer 63 protrude relative to the side surfaces of the stem layer 64.

The upper portion 62 comprises a top layer 65 provided on the stem layer 64 and a cover layer 66 provided on the top layer 65. The top layer 65 and the cover layer 66 have widths greater than the stem layer 64. Both end portions of each of the top layer 65 and the cover layer 66 protrude relative to the side surfaces of the stem layer 64. In the present specification, the side surfaces of the stem layer 64 are assumed to be the side surfaces of the stem layer 64 that extend between the bottom layer 63 and the top layer 65. In the illustrated example, the upper portion 62 has the width greater than the bottom layer 63. The bottom layer 63 may have a width greater than the upper portion 62.

In the display element DE1, the organic layer OR1 contacts the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and contacts the lower portion 61.

In the display element DE2, the organic layer OR2 contacts the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and contacts the lower portion 61.

In the display element DE3, the organic layer OR3 contacts the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and contacts the lower portion 61.

The contact between each of the upper electrodes UE1, UE2, and UE3 and the lower portion 61 includes a case where each of the upper electrodes UE1, UE2, and UE3 directly contacts the upper surface of the bottom layer 63 and a case where each of the upper electrodes UE1, UE2, and UE3 directly contacts the upper surface of the bottom layer 63 and further directly contacts the side surfaces of the stem layer 64. In this specification, the upper surface of the bottom layer 63 is assumed to have, of the bottom layer 63, the surface that directly contacts the stem layer 64 and the surface that protrudes relative to the stem layer 64 and faces the upper portion 62.

In the illustrated example, the subpixel SP1 includes a cap layer CP1 and a sealing layer SE11, the subpixel SP2 includes a cap layer CP2 and a sealing layer SE12, and the subpixel SP3 includes a cap layer CP3 and a sealing layer SE13. The cap layers CP1, CP2 and CP3 function as optical adjustment layers, which improve the extraction efficiency of light emitted from the respective organic layers OR1, OR2, and OR3. The cap layers CP1, CP2, and CP3 may be omitted.

The cap layer CP1 is provided on the upper electrode UE1. The cap layer CP2 is provided on the upper electrode UE2. The cap layer CP3 is provided on the upper electrode UE3.

The sealing layer SE11 is provided on the cap layer CP1, contacts the partition 6, and continuously covers each member of the subpixel SP1. The sealing layer SE11 contacts the stem layer 64 and the upper portion 62 of the partition 6 that surrounds the display element DE1.

The sealing layer SE12 is provided on the cap layer CP2, contacts the partition 6, and continuously covers each member of the subpixel SP2. The sealing layer SE12 contacts the stem layer 64 and the upper portion 62 of the partition 6 that surrounds the display element DE2.

The sealing layer SE13 is provided on the cap layer CP3, contacts the partition 6, and continuously covers each member of the subpixel SP3. The sealing layer SE13 contacts the stem layer 64 and the upper portion 62 of the partition 6 that surrounds the display element DE3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Each of the sealing layers SE11, SE12, and SE13 extends above the partition 6. The edge portion of each of the sealing layers SE11, SE12, and SE13 is located above the partition 6.

None of the stacked films FL1, FL2, and FL3 are provided on the partition 6. Gaps GP are formed between the sealing layer SE11 and the partition 6, between the sealing layer SE12 and the partition 6, and between the sealing layer SE13 and the partition 6.

A transparent resin layer RS1 covers the partition 6 and the sealing layers SE11, SE12, and SE13. The resin layer RS1 fills each of the gaps GP respectively formed between the sealing layer SE11 and the partition 6, between the sealing layer SE12 and the partition 6, and between the sealing layer SE13 and the partition 6.

The sealing layer SE2 covers the resin layer RS1.

A transparent resin layer RS2 is provided on the sealing layer SE2.

Each of the inorganic insulating layer 5, the sealing layers SE11, SE12, and SE13 and the sealing layer SE2 is formed of, for example, an inorganic insulating material such as a silicon nitride (SiNx), a silicon oxide (SiOx), a silicon oxynitride (SiON) or an aluminum oxide (Al₂O₃). For example, the inorganic insulating layer 5 is formed of a silicon oxynitride, and each of the sealing layers SE11, SE12, SE13, and SE2 is formed of a silicon nitride.

The lower portion 61 of the partition 6 is formed of a conductive material and is electrically connected to the upper electrodes UE1, UE2, and UE3. The bottom layer 63 is formed of, for example, a titanium-based material such as titanium or a titanium compound. The stem layer 64 is formed of a material different from the bottom layer 63 and the top layer 65, and is formed of, for example, an aluminum-based material such as aluminum or an aluminum compound.

The upper portion 62 of the partition 6 is formed of, for example, a conductive material. However, the upper portion 62 may be formed of an insulating material. In the illustrated example, the upper portion 62 is formed as a multilayer body of the top layer 65 and the cover layer 66, both of which are formed of conductive materials. The top layer 65 is formed of, for example, a titanium-based material such as titanium or a titanium compound. The cover layer 66 is formed of a material different from the top layer 65 and for example, formed of an oxide conductive material such as an indium tin oxide (ITO).

For example, each of the lower electrodes LE1, LE2, and LE3 is a multilayer body including an oxide conductive layer and a metal layer. The oxide conductive material is formed of an oxide conductive material such as an ITO. The metal layer is formed of a metal material such as silver and functions as a reflective layer. For example, each of the lower electrodes LE1, LE2, and LE3 is a multilayer body including a metal layer between a pair of oxide conductive layers.

The organic layer OR1 has a light emitting layer EM1. The organic layer OR2 has a light emitting layer EM2. The organic layer OR3 has a light emitting layer EM3. The light emitting layers EM1, EM2, and EM3 are formed of materials different from each other. For example, the light emitting layer EM1 is formed of a material that emits light in the blue wavelength range. The light emitting layer EM2 is formed of a material that emits light in the green wavelength range. The light emitting layer EM3 is formed of a material that emits light in the red wavelength range. The light emitting layer EM1 may be formed of a material that emits light in the green wavelength. The light emitting layer EM2 may be formed of a material that emits light in the blue wavelength.

Each of the organic layers OR1, OR2, and OR3 has a plurality of functional layers such as a hole injection layer, a hole transport layer, an electron blocking layer, a hole blocking layer, an electron transport layer, and an electron injection layer.

The upper electrodes UE1, UE2, and UE3 are formed of, for example, a metal material such as an alloy of magnesium and silver (MgAg).

Each of the cap layers CP1, CP2, and CP3 is a multilayer body consisting of a plurality of thin films. All of the thin films are transparent and have refractive indices different from each other.

The circuit layer 11, the organic insulating layer 12, the inorganic insulating layer 5, and the partition 6, which are illustrated, are provided across the display area DA and the surrounding area SA.

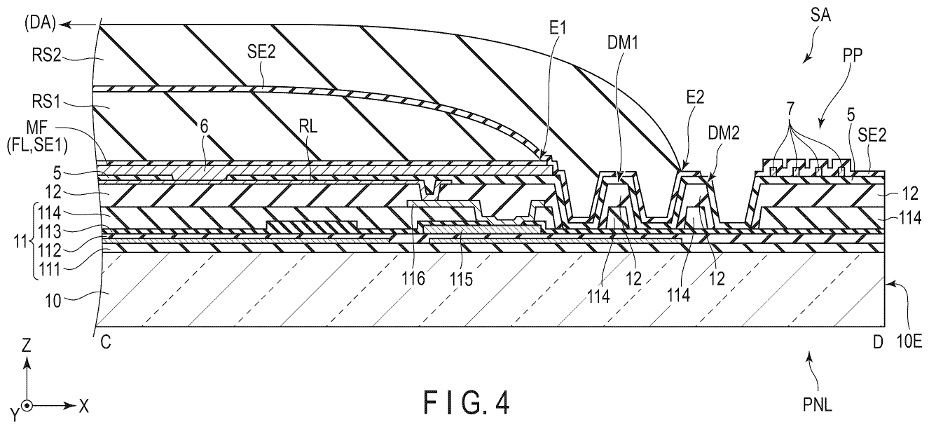

FIG. 4 is a schematic cross-sectional view of the display panel PNL along the C-D line of FIG. 1.

The display panel PNL comprises a dam portion DM1, a dam portion DM2, and the outermost peripheral portion PP in the surrounding area SA. The dam portion DM1, the dam portion DM2 and the outermost peripheral portion PP are located between the display area DA and the substrate edge 10E and are spaced apart from each other. Though not described in detail, these portions each have a ring shape. The number of the dam portions may be one or three or more.

The circuit layer 11 shown in FIG. 3 comprises a plurality of insulating layers 111, 112, 113, and 114, a power supply line 115, and a connection electrode 116. Though not described in detail, the circuit layer 11 comprises each wiring layer and an electrode.

The insulating layer 111 is provided on the substrate 10. The insulating layer 112 is provided on the insulating layer 111. The insulating layer 113 is provided on the insulating layer 112. The insulating layer 114 is provided on the insulating layer 113. The inorganic insulating layers 111, 112, and 113 are formed of inorganic insulating materials, extend up to the substrate edge 10E, and are provided directly under the dam portions DM1 and DM2. The insulating layer 114 is formed of an organic insulating material and is covered by the organic insulating layer 12.

The inorganic insulating layer 5 covers the organic insulating layer 12. The partition 6 extends to the surrounding area SA and is provided on the inorganic insulating layer 5. The power supply line 115 is a line for applying common voltage to the partition 6 and is provided between the insulating layer 112 and the insulating layer 113. The connection electrode 116 is provided between the insulating layer 114 and the organic insulating layer 12 and contacts the power supply line 115 through a through hole of the insulating layer 113 and a through hole of the insulating layer 114. A relay electrode RL is provided between the organic insulating layer 12 and the inorganic insulating layer 5 and contacts the connection electrode 116 through a through hole of the organic insulating layer 12. For example, this relay electrode RL is formed of the same material as the lower electrode LE1. The partition 6 extending to the surrounding area SA contacts the relay electrode RL through a through hole of the inorganic insulating layer 5. Thus, the partition 6 of the display area DA is electrically connected to the power supply line 115 in the surrounding area SA.

Each of the dam portion DM1 and the dam portion DM2 is formed as a stacked layer body of the insulating layer 114 and the organic insulating layer 12, is provided on the insulating layer 113, and is covered by the inorganic insulating layer 5.

In the surrounding area SA, a multilayer film MF is located above the organic insulating layer 12 and is provided on the partition 6. The multilayer film MF comprises a stacked film FL and a sealing layer SE1 provided on the stacked film FL. In the illustrated example, the multilayer film MF is not provided above the dam portion DM1, the dam portion DM2, and the outermost peripheral portion PP.

Here, the stacked film FL is any one of the stacked films FL1, FL2, and FL3 shown in FIG. 3. For example, when the stacked film FL is the stacked film FL3, the stacked film FL is formed as a stacked layer body of thin films respectively formed of the same material as the organic layer OR3, the upper electrode UE3, and the cap layer CP3.

Here, the sealing layer SE1 is any one of the sealing layers SE11, SE12, and SE13 shown in FIG. 3. For example, when the stacked film FL is the stacked film FL3, the sealing layer SE1 is the sealing layer SE13.

The resin layer RS1 is provided on the multilayer film MF (or the sealing layer SE1). In the illustrated example, an end portion E1 of the resin layer RS1 is located directly above the multilayer film MF.

The sealing layer SE2 covers the resin layer RS1. The sealing layer SE2 extends outward beyond the end portion E1 and contacts the inorganic insulating layer 5. This configuration causes the resin layer RS1 to be surrounded by the sealing layer SE1 and the sealing layer SE2 and be sealed. This configuration suppresses moisture intrusion to the resin layer RS1.

The resin layer RS2 is provided on the sealing layer SE2. An end portion E2 of the resin layer RS2 is located between the end portion E1 and the substrate edge 10E. In the illustrated example, the end portion E2 overlaps the dam portion DM2.

The outermost peripheral portion PP is the area closest to the substrate edge 10E in the display panel PNL. In the illustrated example, the outermost peripheral portion PP is spaced apart from the dam portion DM2. Alternatively, the outermost peripheral portion PP may be connected to the dam portion DM2.

In the outermost peripheral portion PP, the insulating layer 114 is provided on the insulating layer 113 and is covered by the organic insulating layer 12. The inorganic insulating layer 5 covers the organic insulating layer 12 and, in the area between the dam portion DM2 and the outermost peripheral portion PP, contacts the insulating layer 113.

This outermost peripheral portion PP comprises a plurality of surrounding partitions 7. As described in detail later, each surrounding partition 7 is formed in an overhang shape in the same manner as the partition 6 and is provided between the inorganic insulating layer 5 and the sealing layer SE2.

The display panel PNL having such a configuration can be obtained by separating a mother substrate. For example, if a cutting line is set between the dam portion DM2 and the outermost peripheral portion PP in the figure when the mother substrate is separated, the display panel PNL does not comprise the outermost peripheral portion PP including the surrounding partitions 7 illustrated. That is, depending on the setting of the cutting line on the mother substrate, the outermost peripheral portion PP may or may not be present in the display panel PNL.

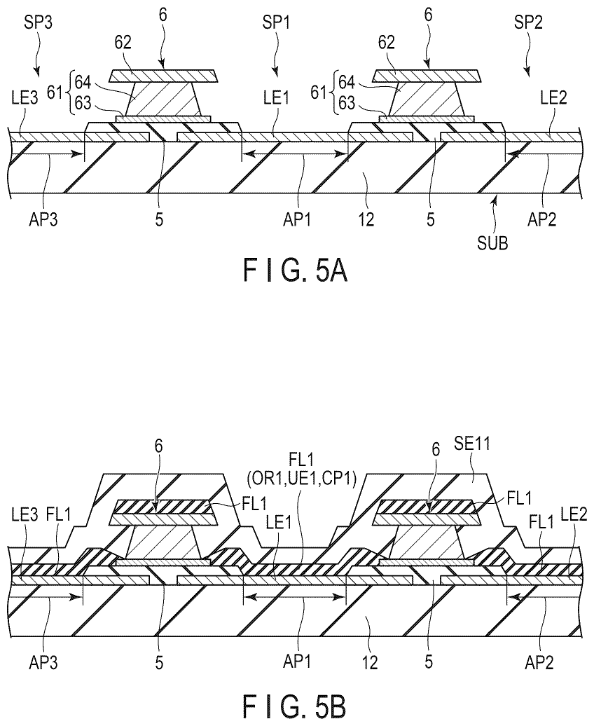

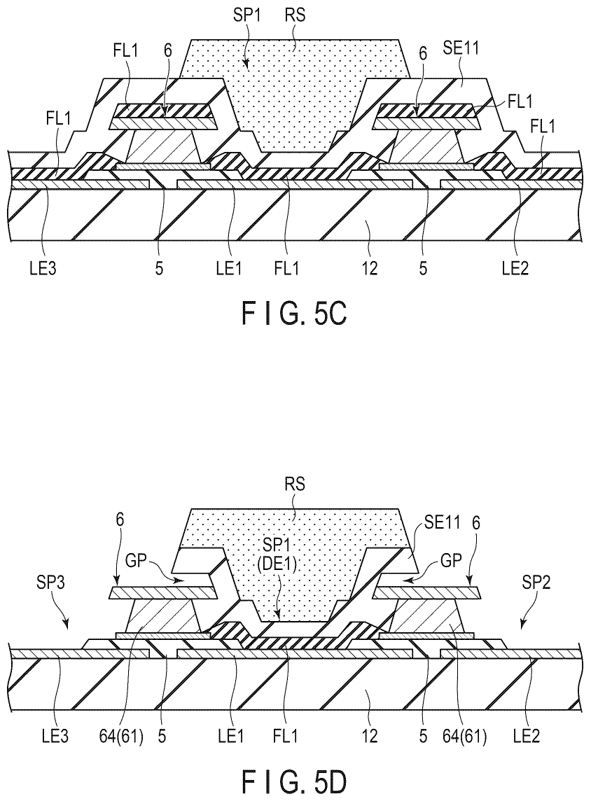

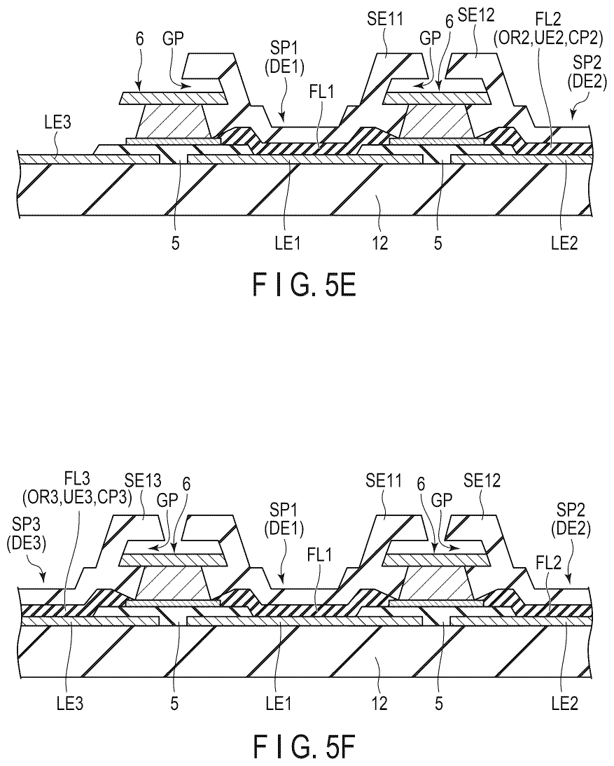

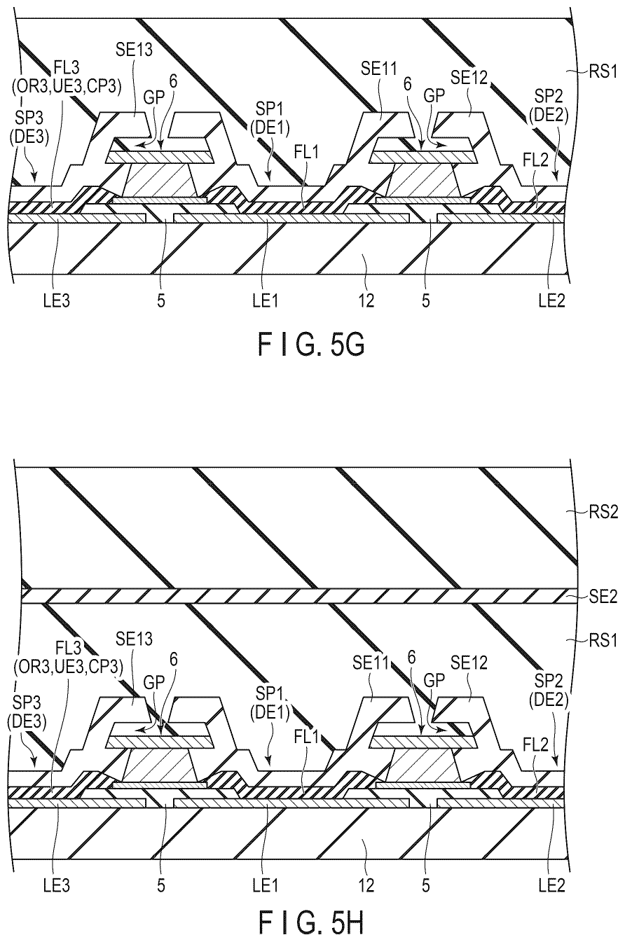

The following describes an example of the manufacturing method of the display device DSP with reference to FIG. 5A to FIG. 5H. FIG. 5A to FIG. 5H are cross-sectional views of a processing substrate SUB along the A-B line of FIG. 2 and omit the illustration of the elements below the organic insulating layer 12. The processing substrate SUB corresponds to, for example, a large mother substrate for collective manufacturing of a plurality of display panels.

First, as shown in FIG. 5A, the processing substrate SUB is prepared. The step of preparing the processing substrate SUB includes a step of forming the organic insulating layer 12, a step of forming on the organic insulating layer 12 the lower electrode LE1 of the subpixel SP1, the lower electrode LE2 of the subpixel SP2, and the lower electrode LE3 of the subpixel SP3, a step of forming the inorganic insulating layer 5 having apertures AP1, AP2, and AP3 respectively overlapping the lower electrodes LE1, LE2, and LE3, and a step of forming the partition 6 having the lower portion 61 located on the inorganic insulating layer 5 and the upper portion 62 located on the lower portion 61. The partition 6 may be formed after the formation of the inorganic insulating layer 5 having the apertures AP1, AP2, and AP3. Alternatively, the apertures AP1, AP2, and AP3 may be formed in the inorganic insulating layer 5 after the formation of the partition 6. The surrounding partition 7 is formed in the process of forming the partition 6 as well.

Subsequently, the display element DE1 is formed.

First, as shown in FIG. 5B, vapor deposition using the partition 6 as a mask is performed to form the stacked film FL1. The stacked film FL1 comprises the organic layer OR1 including the light emitting layer EM1, the upper electrode UE1, and the cap layer CP1. The organic layer OR1, the upper electrode UE1, and the cap layer CP1 are successively formed by an evaporation device in a vacuum state.

At this time, the stacked film FL1 is separated by the partition 6 having an overhang shape. That is, parts provided on the lower electrodes LE1, LE2, and LE3 of the stacked film FL1 are spaced apart from parts of the stacked film FL1 provided on the partition 6.

Then, the sealing layer SE11 is formed to continuously cover the stacked film FL1 and the partition 6. The sealing layer SE11 is formed by depositing inorganic insulating materials (for example, a silicon nitride) on the processing substrate SUB in a Chemical Vapor Deposition (CVD) device.

The stacked film FL1 and the sealing layer SE11 are substantially formed in the entire processing substrate SUB and are provided in the display area DA and the surrounding area SA. In the display area DA, the stacked film FL1 and the sealing layer SE11 are provided not only in the subpixel SP1 but also in the subpixels SP2 and SP3.

Subsequently, as shown in FIG. 5C, a resist RS patterned into a predetermined shape is formed on the sealing layer SE11. The resist RS overlaps the subpixel SP1 and part of the partition 6 around the subpixel SP1.

Subsequently, as shown in FIG. 5D, the sealing layer SE11 and the stacked film FL1 are patterned using the resist RS as a mask. Various etching processes using the resist RS as a mask removes the sealing layer SE11 exposed from the resist RS followed by, sequential removal of the cap layer CP1, the upper electrode UE1, and the organic layer OR1 included in the stacked film FL1.

This patterning removes the stacked film FL1 and the sealing layer SE11 located directly above the lower electrode LE2 and the lower electrode LE3. Thus, the lower electrode LE2 is exposed in the subpixel SP2, and the lower electrode LE3 is exposed in the subpixel SP3. In the surrounding area SA as well, the stacked film FL1 and the sealing layer SE11 are removed.

Then, the resist RS is removed. Thus, the display element DE1 is formed in the subpixel SP1. Further, the stacked film FL1 formed on the partition 6 is removed in the process between the patterning of the stacked film FL1 and the removal of the resist RS. Thus, the gap GP is formed between the sealing layer SE11 and the partition 6.

Subsequently, as shown in FIG. 5E, the display element DE2 is formed. The procedure of forming the display element DE2 is the same as that of forming the display element DE1. That is, the stacked film FL2 is formed on the lower electrode LE2. The stacked film FL2 comprises the organic layer OR2 including the light emitting layer EM2, the upper electrode UE2, and the cap layer CP2. Subsequently, the sealing layer SE12 is formed on the stacked film FL2. Then, a resist is formed on the sealing layer SE12. Then, patterning is performed using this resist as a mask. Thus, the sealing layer SE12 and the stacked film FL2 exposed from the resist are removed. Then, the resist is removed.

Thus, the display element DE2 is formed in the subpixel SP2. Thus, the lower electrode LE3 of the subpixel SP3 is exposed. In the illustrated example, the stacked film FL2 on the partition 6 is removed during the patterning and thus the gap GP is formed between the sealing layer SE12 and the partition 6.

Subsequently, as shown in FIG. 5F, the display element DE3 is formed. The procedure of forming the display element DE3 is the same as that of forming the display element DE1. That is, the stacked film FL3 is formed on the lower electrode LE3. The stacked film FL3 comprises the organic layer OR3 including the light emitting layer EM3, the upper electrode UE3, and the cap layer CP3. Subsequently, the sealing layer SE13 is formed on the stacked film FL3. Then, a resist is formed on the sealing layer SE13. Then, patterning is performed using this resist as a mask. Thus, the sealing layer SE13 and the stacked film FL3 exposed from the resist are removed. Then, the resist is removed.

Thus, the display element DE3 is formed in the subpixel SP3. In the illustrated example, the stacked film FL3 on the partition 6 is removed during the patterning and thus the gap GP is formed between the sealing layer SE13 and the partition 6.

The above-described manufacturing process assumes a case where the display element DE1 is formed firstly, and the display element DE2 is formed secondly, and the display element DE3 is formed lastly. However, the formation order of the display elements DE1, DE2, and DE3 is not limited to this example.

Subsequently, as shown in FIG. 5G, after the formation of the display element DE3, an organic insulating material is applied and cured to form the resin layer RS1. The resin layer RS1 fills the gap GP.

Subsequently, as shown in FIG. 5H, the sealing layer SE2 is formed by depositing an inorganic insulating material (for example, a silicon nitride). Then, an organic insulating material is applied and cured to form the resin layer RS2.

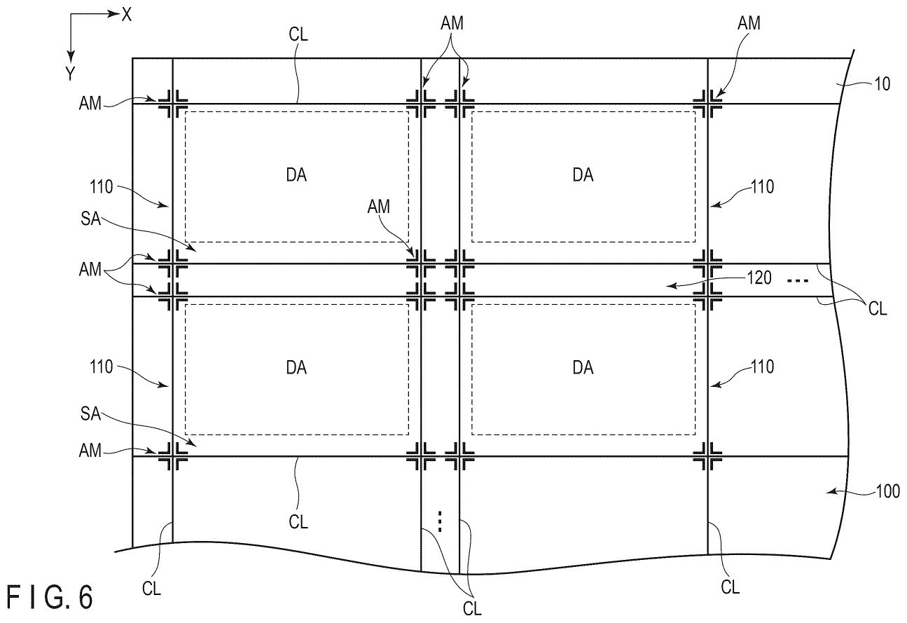

FIG. 6 is a schematic plan view showing part of a mother substrate 100.

The mother substrate 100 formed through the steps shown in FIG. 5A to FIG. 5H comprises, on the large substrate 10, a plurality of panel portions 110 and a margin portion 120 between adjacent panel portions 110. The margin portion 120 is the area outside the display area DA of each panel portion 110 and is part of the surrounding area SA. The plurality of panel portions 110 are arranged in the matrix in the first direction X and the second direction Y.

A plurality of cutting lines CL include, for example, cutting lines extending in the first direction X and cutting lines extending in the second direction Y, and are set to surround each of the panel portions 110. Each of the panel portions 110 is obtained by separating the mother substrate 100 along the cutting line CL. For example, each obtained panel portion 110 corresponds to the display panel PNL shown in FIG. 1 and comprises the display area DA.

At the intersection portion of the cutting line CL, the alignment mark AM is formed in an L-shape along the cutting line CL. A cross-shaped space is formed between four alignment marks AM. The cutting line CL extending in the first direction X is located between two alignment marks AM adjacent in the second direction Y, and the cutting line CL extending in the second direction Y is located between two alignment marks AM adjacent in the first direction X. Thus, at the intersection portion of the cutting lines CL, one alignment mark AM is located in the panel portion 110 and three alignment marks AM are located in the margin portion 120.

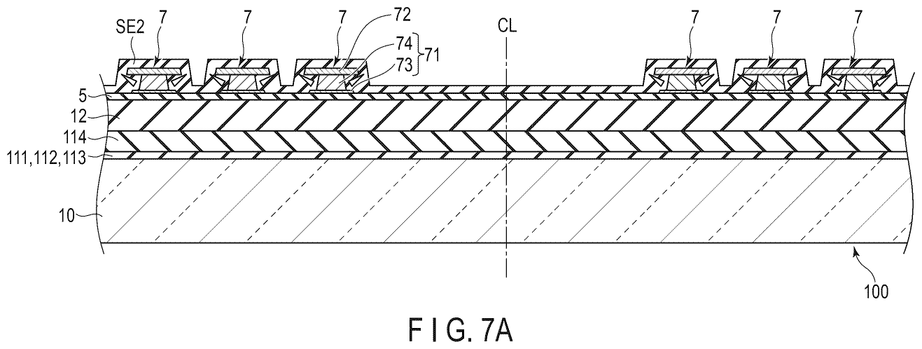

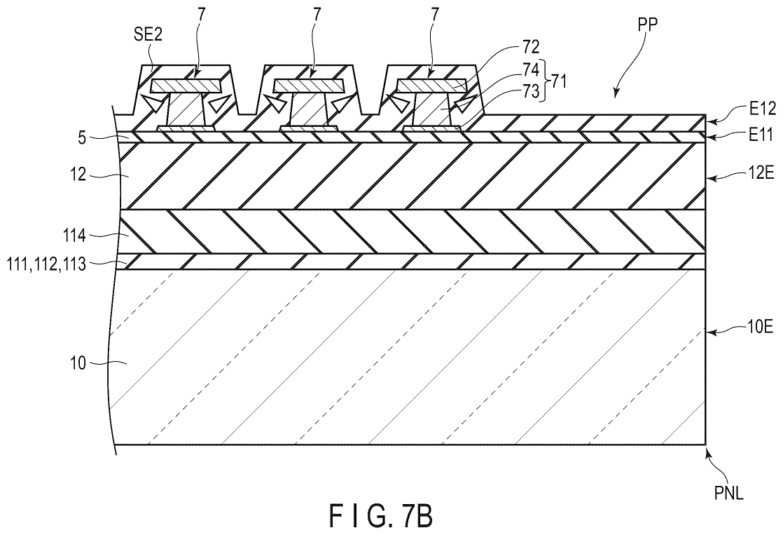

FIG. 7A is a schematic cross-sectional view showing a configuration example of the mother substrate 100 in the vicinity of the cutting line CL shown in FIG. 6.

At the cutting line CL, the insulating layers 111, 112, 113, and 114 are provided on the substrate 10, the organic insulating layer 12 is provided on the insulating layer 114, the inorganic insulating layer 5 is provided on the organic insulating layer 12, and the sealing layer SE2 is provided on the inorganic insulating layer 5. The resin layer RS1 and the resin layer RS2 in the display area DA shown in FIG. 5H do not overlap the surrounding partitions 7 and the cutting line CL.

Each of the surrounding partitions 7 comprises a lower portion 71 and an upper portion 72 in the same manner as the partition 6 shown in FIG. 3. The lower portion 71 comprises a bottom layer 73 provided on the inorganic insulating layer 5 and a stem layer 74 provided between the bottom layer 73 and the upper portion 72. The bottom layer 73 is formed of the same material as the bottom layer 63, and the stem layer 74 is formed of the same material as the stem layer 64. Though not described in detail, the upper portion 72 includes a top layer formed of the same material as the top layer 65 and a cover layer formed of the same material as the cover layer 66. Both end portions of the bottom layer 73 protrude relative to the side surfaces of the stem layer 74. Both end portions of the upper portion 72 protrude relative to the side surfaces of the stem layer 74.

In the illustrated cross section, none of the surrounding partitions 7 is provided at the cutting line CL. The interval between the surrounding partitions 7 adjacent across the cutting line CL (the interval between the upper portions 72) is approximately 20 μm to 50 μm.

The sealing layer SE2 directly covers the surrounding partition 7. That is, the sealing layer SE2 contacts the bottom layer 73, the stem layer 74, and the upper portion 72. Further, the sealing layer SE2 contacts the inorganic insulating layer 5 between the adjacent surrounding partitions 7.

The mother substrate 100 having this configuration is separated by a cutter along the cutting line CL. A cutter that is located at the cutting line CL does not contact the surrounding partition 7. Even slightly deviated from the cutting line CL, the cutter does not contact the surrounding partitions 7. Thus, compared with a case where the cutter frequently contacts the surrounding partition 7, a longer service life of a cutter blade can be achieved. Thus, the replacement frequency of the cutter blade is reduced, and an increase in manufacturing cost can be suppressed.

FIG. 7B is a schematic cross-sectional view showing the outermost peripheral portion PP of the display panel PNL separated along the cutting line CL shown in FIG. 7A.

The organic insulating layer 12 has an end portion 12E directly above the substrate edge 10E. The inorganic insulating layer 5 has an end portion E11 provided on the organic insulating layer 12 directly above the substrate edge 10E. That is, the end portion E11 is located on the end portion 12E. The sealing layer SE2 has an end portion E12 provided on the inorganic insulating layer 5 directly above the substrate edge 10E. That is, the end portion E12 is located on the end portion E11.

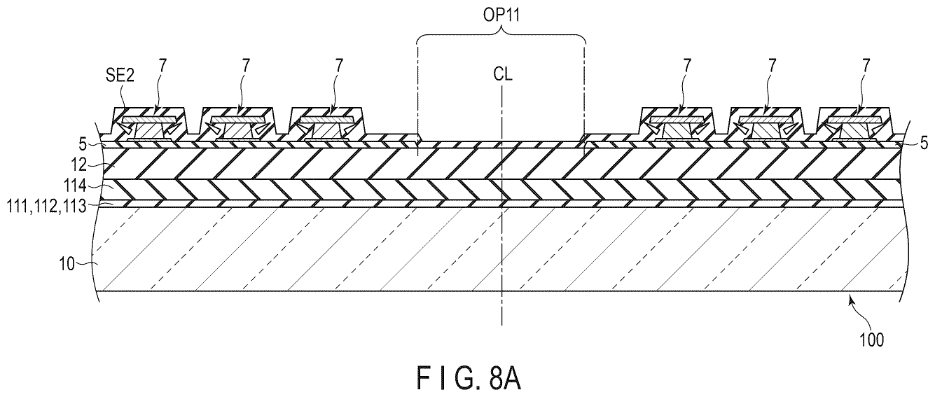

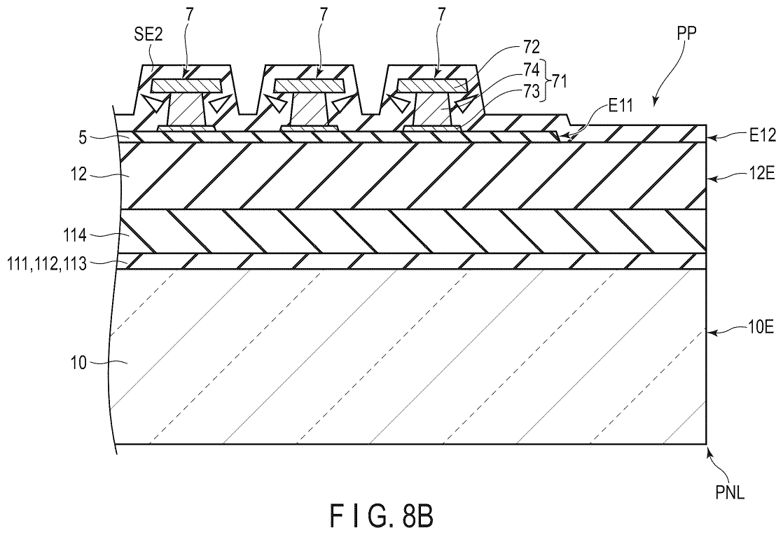

FIG. 8A is a cross-sectional view schematically showing another configuration example of the mother substrate 100 in the vicinity of the cutting line CL.

The configuration example shown in FIG. 8A differs from the configuration example shown in FIG. 7A in that the inorganic insulating layer 5 has an aperture OP11 overlapping the cutting line CL. The sealing layer SE2 covers the surrounding partition 7 and is provided on the inorganic insulating layer 5. At the cutting line CL, the sealing layer SE2 is provided on the organic insulating layer 12 through the aperture OP11. Part of the organic insulating layer 12 exposed from the inorganic insulating layer 5 is covered by the sealing layer SE2.

That is, the inorganic insulating layer 5 is not provided at the cutting line CL, and a stacked layer body of the insulating layers 111, 112, 113, and 114, the organic insulating layer 12, and the sealing layer SE2 is formed on the substrate 10.

This configuration example also prevents the cutter from contacting the surrounding partition 7 when the mother substrate 100 is separated. Thus, the configuration example achieves the same effects as those of the configuration example shown in FIG. 7A.

Further, the inorganic insulating layer 5 is absent on the organic insulating layer 12 at the cutting line CL. Thus, when the mother substrate 100 is separated, the configuration can prevent a defect in which fragments of the inorganic insulating layer 5 become foreign matter. Thus, the configuration can suppress a decrease in manufacturing yield.

FIG. 8B is a schematic cross-sectional view showing the outermost peripheral portion PP of the display panel PNL separated along the cutting line CL shown in FIG. 8A.

The organic insulating layer 12 has the end portion 12E directly above the substrate edge 10E. The inorganic insulating layer 5 is not provided directly above the substrate edge 10E and has the end portion E11 between the outermost surrounding partition 7 and the substrate edge 10E. The sealing layer SE2 covers the end portion E11 and has the end portion E12 provided on the organic insulating layer 12 directly above the substrate edge 10E. That is, the end portion E12 is located on the end portion 12E.

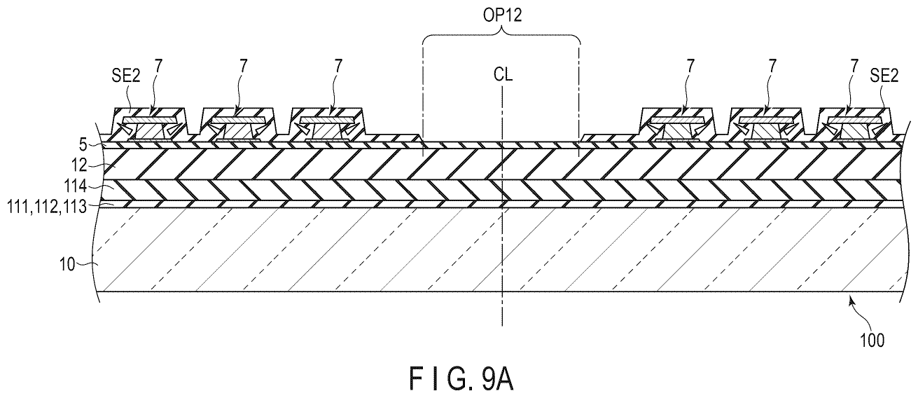

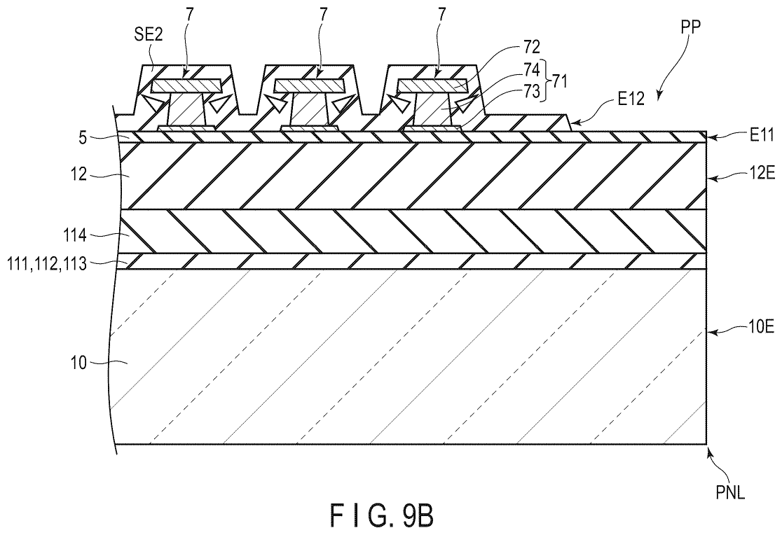

FIG. 9A is a cross-sectional view schematically showing another configuration example of the mother substrate 100 in the vicinity of the cutting line CL.

The configuration example shown in FIG. 9A differs from the configuration example shown in FIG. 7A in that the sealing layer SE2 has an aperture OP12 overlapping the cutting line CL.

The inorganic insulating layer 5 is provided on the organic insulating layer 12 at the cutting line CL. The sealing layer SE2 covers the surrounding partition 7 and is provided on the inorganic insulating layer 5. The area including the cutting line CL of the inorganic insulating layer 5 is exposed from the sealing layer SE2.

That is, the sealing layer SE2 is not provided at the cutting line CL, and a stacked layer body of the insulating layers 111, 112, 113, and 114, the organic insulating layer 12, and the inorganic insulating layer 5 is formed on the substrate 10.

This configuration example also prevents the cutter from contacting the surrounding partition 7 when the mother substrate 100 is separated. Thus, the configuration example achieves the same effects as those of the configuration example shown in FIG. 7A.

Further, the sealing layer SE2 is absent on the organic insulating layer 12 at the cutting line CL. Thus, when the mother substrate 100 is separated, the configuration can prevent a defect in which fragments of the sealing layer SE2 become foreign matter. Thus, the configuration can suppress a decrease in manufacturing yield.

FIG. 9B is a schematic cross-sectional view showing the outermost peripheral portion PP of the display panel PNL separated along the cutting line CL shown in FIG. 9A.

The organic insulating layer 12 has the end portion 12E directly above the substrate edge 10E. The inorganic insulating layer 5 has the end portion E11 provided on the organic insulating layer 12 directly above the substrate edge 10E. That is, the end portion E11 is located on the end portion 12E. The sealing layer SE2 is provided on the inorganic insulating layer 5, is not provided directly above the substrate edge 10E, and has the end portion E12 between the outermost surrounding partition 7 and the substrate edge 10E.

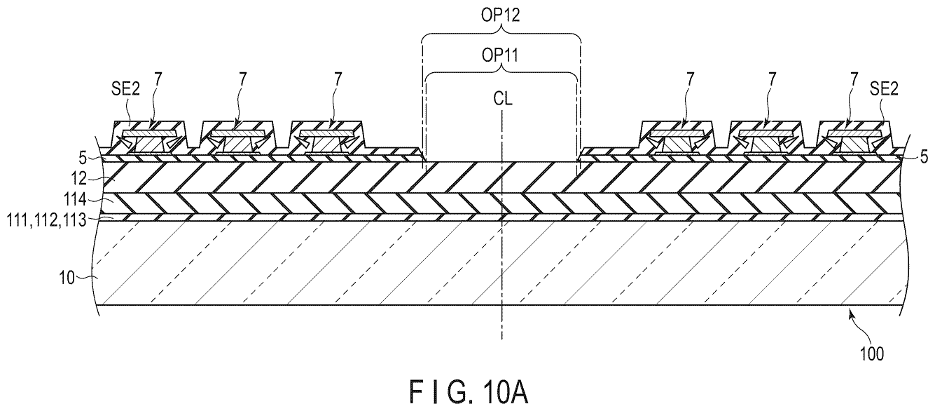

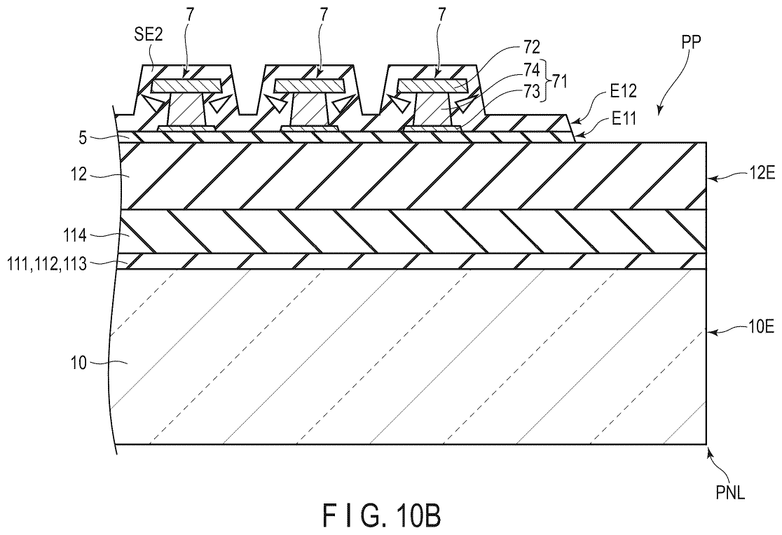

FIG. 10A is a cross-sectional view schematically showing another configuration example of the mother substrate 100 in the vicinity of the cutting line CL.

The configuration example shown in FIG. 10A differs from the configuration example shown in FIG. 7A in that the inorganic insulating layer 5 has the aperture OP11 overlapping the cutting line CL and the sealing layer SE2 has the aperture OP12 overlapping the aperture OP11 at the cutting line CL. The sealing layer SE2 covers the surrounding partition 7 and is provided on the inorganic insulating layer 5. The area including the cutting line CL of the organic insulating layer 12 is exposed from the inorganic insulating layer 5 and the sealing layer SE2.

That is, the inorganic insulating layer 5 and the sealing layer SE2 are not provided at the cutting line CL, and a stacked layer body of the insulating layers 111, 112, 113, and 114 and the organic insulating layer 12 is formed on the substrate 10.

This configuration example also prevents the cutter from contacting the surrounding partition 7 when the mother substrate 100 is separated. Thus, the configuration example achieves the same effects as those of the configuration example shown in FIG. 7A.

Further, the inorganic insulating layer 5 and the sealing layer SE2 are absent on the organic insulating layer 12 at the cutting line CL. Thus, when the mother substrate 100 is separated, the configuration can prevent a defect in which fragments of the inorganic insulating layer 5 and the sealing layer SE2 become foreign matter. Thus, the configuration can suppress a decrease in manufacturing yield.

FIG. 10B is a schematic cross-sectional view showing the outermost peripheral portion PP of the display panel PNL separated along the cutting line CL shown in FIG. 10A.

The organic insulating layer 12 has the end portion 12E directly above the substrate edge 10E. The inorganic insulating layer 5 is not provided directly above the substrate edge 10E and has the end portion E11 between the outermost surrounding partition 7 and the substrate edge 10E. The sealing layer SE2 is provided on the inorganic insulating layer 5, is not provided directly above the substrate edge 10E, and has an end portion E12 between the outermost surrounding partition 7 and the substrate edge 10E. In the illustrated example, the end portion E12 is located on the end portion E11.

In the above configuration examples, the sealing layer SE2 directly covers the surrounding partition 7. The following describes cases where another sealing layer SE3 is interposed between the surrounding partition 7 and the sealing layer SE2. This sealing layer SE3 is formed by depositing an inorganic insulating material (for example, a silicon nitride) before forming the resin layer RS1 shown in FIG. 5G. That is, in the display area DA, the sealing layer SE3 is provided between the sealing layers SE11, SE12, and SE13 and the resin layer RS1.

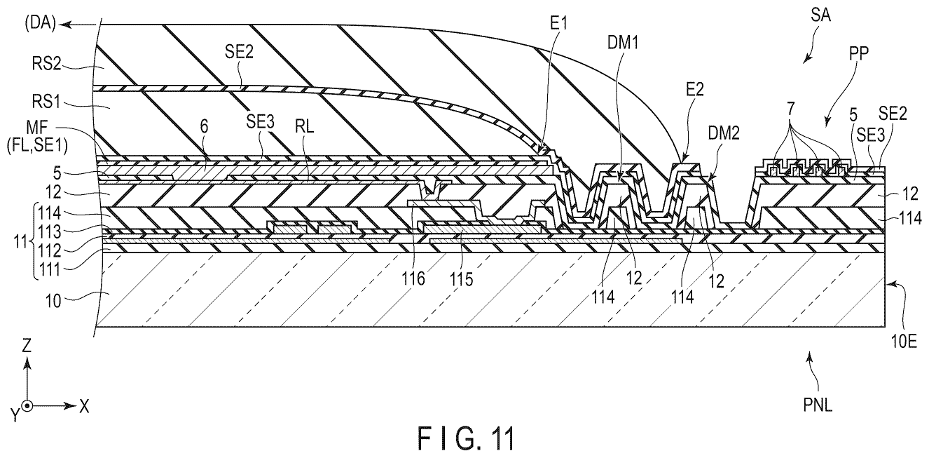

FIG. 11 is a schematic cross-sectional view of another configuration example of the display panel PNL along the C-D line of FIG. 1.

The configuration example shown in FIG. 11 differs from the configuration example shown in FIG. 4 in that the sealing layer SE3 is provided between the multilayer film MF and the resin layer RS1. The sealing layer SE3 covers the multilayer film MF and the partition 6 and contacts the inorganic insulating layer 5. The resin layer RS1 is provided on the sealing layer SE3. The sealing layer SE2 covers the resin layer RS1 and contacts the sealing layer SE3 outside the end portion E1 of the resin layer RS1. That is, the resin layer RS1 is surrounded by the sealing layer SE3 and the sealing layer SE2 and is sealed. This configuration suppresses moisture intrusion to the resin layer RS1.

In the outermost peripheral portion PP, the insulating layer 114 is provided on the insulating layer 113 and is covered by the organic insulating layer 12. The inorganic insulating layer 5 covers the organic insulating layer 12 and, in the area between the dam portion DM2 and the outermost peripheral portion PP, contacts the insulating layer 113. The surrounding partition 7 is provided between the inorganic insulating layer 5 and the sealing layer SE2. The sealing layer SE3 is provided between the surrounding partition 7 and the sealing layer SE2.

The following describes configuration examples where the sealing layer SE3 is provided.

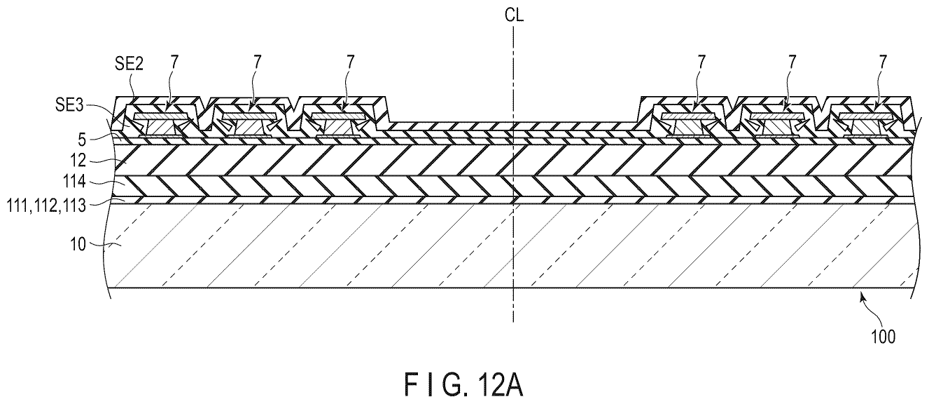

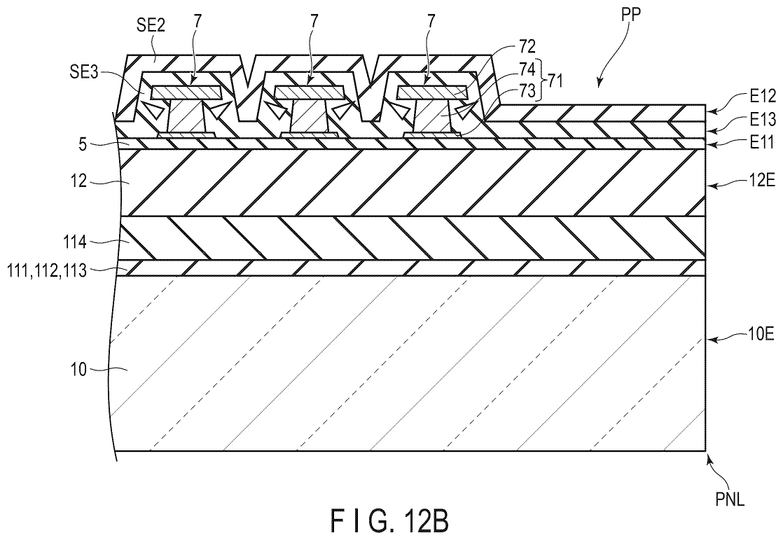

FIG. 12A is a schematic cross-sectional view showing a configuration example of the mother substrate 100 in the vicinity of a cutting line CL shown in FIG. 6.

At the cutting line CL, the insulating layers 111, 112, 113, and 114 are provided on the substrate 10, the organic insulating layer 12 is provided on the insulating layer 114, the inorganic insulating layer 5 is provided on the organic insulating layer 12, the sealing layer SE3 is provided on the inorganic insulating layer 5, and the sealing layer SE2 is provided on the sealing layer SE3. The resin layer RS1 and the resin layer RS2 in the display area DA do not overlap the surrounding partitions 7 and the cutting line CL.

In the illustrated cross section, none of the surrounding partitions 7 is provided at the cutting line CL. The interval between the surrounding partitions 7 adjacent across the cutting line CL (the interval between the upper portions 72) is approximately 20 μm to 50 μm.

The sealing layer SE3 directly covers the surrounding partition 7. That is, the sealing layer SE3 contacts the bottom layer 73, the stem layer 74, and the upper portion 72. Further, the sealing layer SE3 contacts the inorganic insulating layer 5 between the adjacent surrounding partitions 7.

This configuration example also prevents the cutter from contacting the surrounding partition 7 when the mother substrate 100 is separated. Thus, the configuration example achieves the same effects as those of the configuration example shown in FIG. 7A.

FIG. 12B is a schematic cross-sectional view showing the outermost peripheral portion PP of the display panel PNL separated along the cutting line CL shown in FIG. 12A.

The organic insulating layer 12 has the end portion 12E directly above the substrate edge 10E. The inorganic insulating layer 5 has the end portion E11 provided on the organic insulating layer 12 directly above the substrate edge 10E. That is, the end portion E11 is located on the end portion 12E. The sealing layer SE3 has an end portion E13 provided on the inorganic insulating layer 5 directly above the substrate edge 10E. That is, the end portion E13 is located on the end portion E11. The sealing layer SE2 has the end portion E12 provided on the sealing layer SE3 directly above the substrate edge 10E. That is, the end portion E12 is located on the end portion E13.

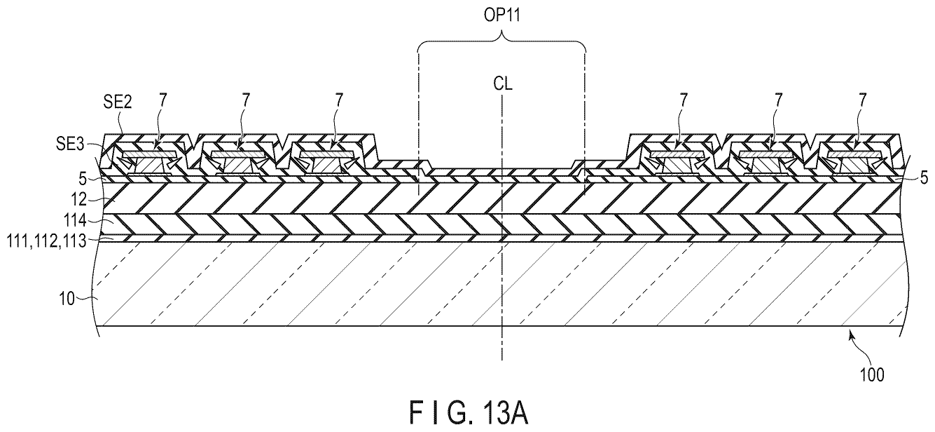

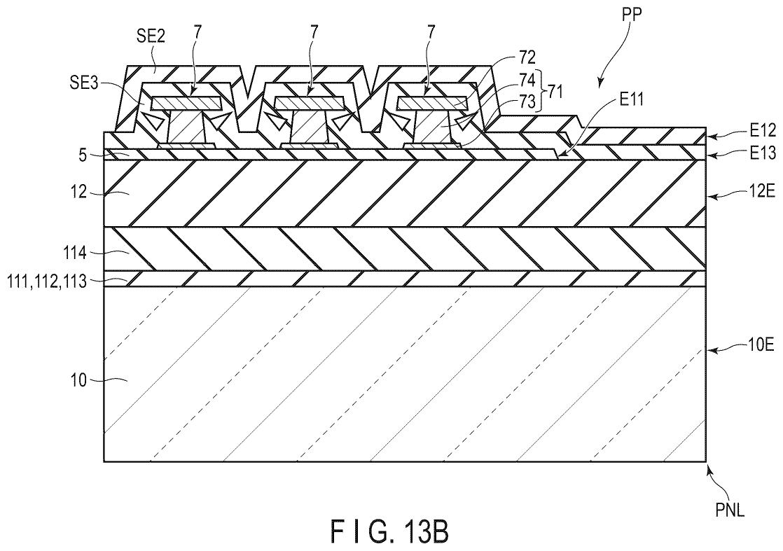

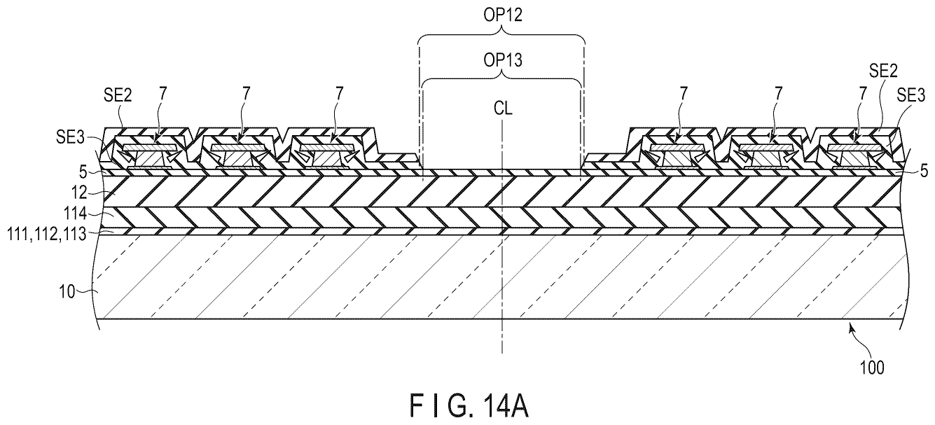

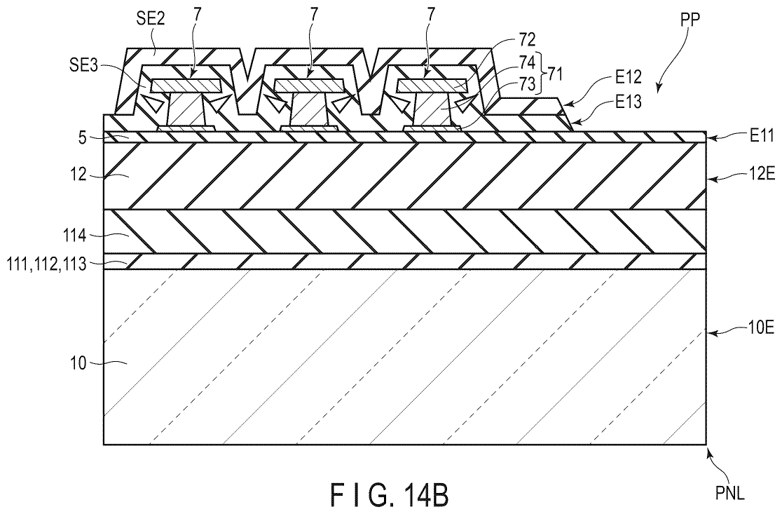

FIG. 13A is a cross-sectional view schematically showing another configuration example of the mother substrate 100 in the vicinity of the cutting line CL.

The configuration example shown in FIG. 13A differs from the configuration example shown in FIG. 12A in that the inorganic insulating layer 5 has the aperture OP11 overlapping the cutting line CL. The sealing layer SE3 covers the surrounding partition 7 and is provided on the inorganic insulating layer 5. At the cutting line CL, the sealing layer SE3 is provided on the organic insulating layer 12 through the aperture OP11. Part of the organic insulating layer 12 exposed from the inorganic insulating layer 5 is covered by the sealing layer SE3. The sealing layer SE2 is provided on the sealing layer SE3 at the cutting line CL.

That is, the inorganic insulating layer 5 is not provided at the cutting line CL, and a stacked layer body of the insulating layers 111, 112, 113, and 114, the organic insulating layer 12, the sealing layer SE3, and the sealing layer SE2 is formed on the substrate 10.

This configuration example also prevents the cutter from contacting the surrounding partition 7 when the mother substrate 100 is separated. Thus, the configuration example achieves the same effects as those of the configuration example shown in FIG. 7A.

Further, the inorganic insulating layer 5 is absent on the organic insulating layer 12 at the cutting line CL. Thus, when the mother substrate 100 is separated, the configuration can prevent a defect in which fragments of the inorganic insulating layer 5 become foreign matter. Thus, the configuration can suppress a decrease in manufacturing yield.

FIG. 13B is a schematic cross-sectional view showing the outermost peripheral portion PP of the display panel PNL separated along the cutting line CL shown in FIG. 13A.

The organic insulating layer 12 has the end portion 12E directly above the substrate edge 10E. The inorganic insulating layer 5 is not provided directly above the substrate edge 10E and has the end portion E11 between the outermost surrounding partition 7 and the substrate edge 10E. The sealing layer SE3 covers the end portion E11 and has the end portion E13 provided on the organic insulating layer 12 directly above the substrate edge 10E. That is, the end portion E13 is located on the end portion 12E. The sealing layer SE2 has the end portion E12 provided on the sealing layer SE3 directly above the substrate edge 10E. That is, the end portion E12 is located on the end portion E13.

FIG. 14A is a cross-sectional view schematically showing another configuration example of the mother substrate 100 in the vicinity of the cutting line CL.

The configuration example shown in FIG. 14A differs from the configuration example shown in FIG. 12A in that the sealing layer SE3 has an aperture OP13 overlapping the cutting line CL and the sealing layer SE2 has the aperture OP12 overlapping the aperture OP13 at the cutting line CL.

The inorganic insulating layer 5 is provided on the organic insulating layer 12 at the cutting line CL. The sealing layer SE3 covers the surrounding partition 7 and is provided on the inorganic insulating layer 5. The area including the cutting line CL of the inorganic insulating layer 5 is exposed from the sealing layer SE3 and the sealing layer SE2.

That is, the sealing layer SE3 and the sealing layer SE2 are not provided at the cutting line CL, and a stacked layer body of the insulating layers 111, 112, 113, and 114, the organic insulating layer 12, and the inorganic insulating layer 5 is formed on the substrate 10.

This configuration example also prevents the cutter from contacting the surrounding partition 7 when the mother substrate 100 is separated. Thus, the configuration example achieves the same effects as those of the configuration example shown in FIG. 7A.

Further, the sealing layers SE3 and SE2 are absent on the organic insulating layer 12 at the cutting line CL. Thus, when the mother substrate 100 is separated, the configuration can prevent a defect in which fragments of the sealing layer SE3 and the sealing layer SE2 become foreign matter. Thus, the configuration can suppress a decrease in manufacturing yield.

FIG. 14B is a schematic cross-sectional view showing the outermost peripheral portion PP of the display panel PNL separated along the cutting line CL shown in FIG. 14A.

The organic insulating layer 12 has the end portion 12E directly above the substrate edge 10E. The inorganic insulating layer 5 has the end portion E11 provided on the organic insulating layer 12 directly above the substrate edge 10E. That is, the end portion E11 is located on the end portion 12E. The sealing layer SE3 is provided on the inorganic insulating layer 5, is not provided directly above the substrate edge 10E, and has the end portion E13 between the outermost surrounding partition 7 and the substrate edge 10E. The sealing layer SE2 is provided on the sealing layer SE3, is not provided directly above the substrate edge 10E, and has the end portion E12 between the outermost surrounding partition 7 and the substrate edge 10E. In the illustrated example, the end portion E12 is located on the end portion E13.

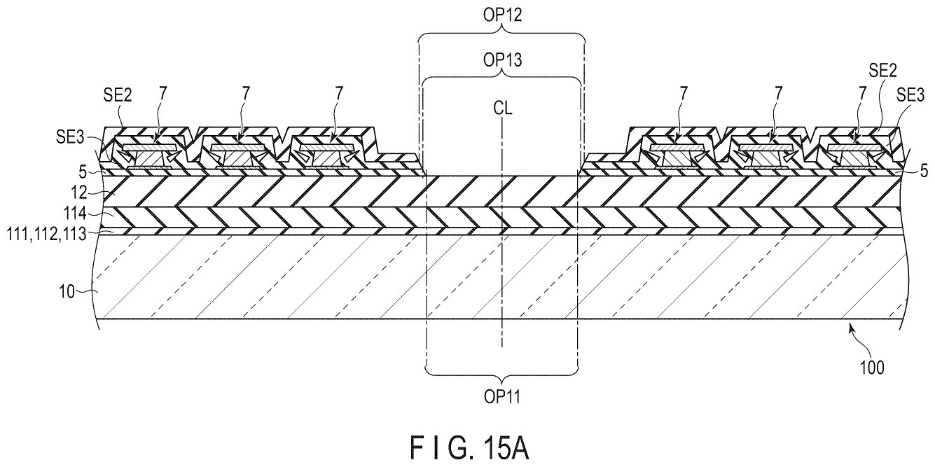

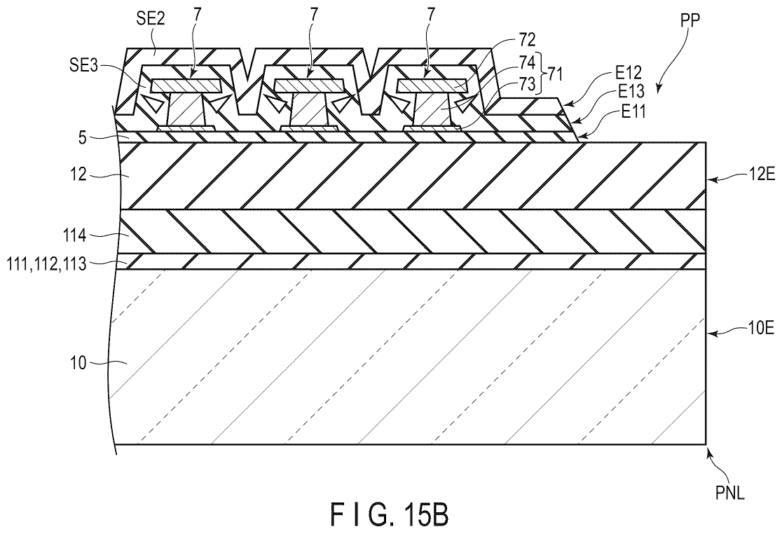

FIG. 15A is a cross-sectional view schematically showing another configuration example of the mother substrate 100 in the vicinity of the cutting line CL.

The configuration example shown in FIG. 15A differs from the configuration example shown in FIG. 12A in that the inorganic insulating layer 5 has the aperture OP11 overlapping the cutting line CL, the sealing layer SE3 has the aperture OP13 overlapping the aperture OP11 at the cutting line CL, and the sealing layer SE2 has the aperture OP12 overlapping the third aperture OP13 at the cutting line CL.

The sealing layer SE3 covers the surrounding partition 7 and is provided on the inorganic insulating layer 5. The area including the cutting line CL of the organic insulating layer 12 is exposed from the inorganic insulating layer 5, the sealing layer SE3, and the sealing layer SE2.

That is, the inorganic insulating layer 5, the sealing layer SE3, and the sealing layer SE2 are not provided at the cutting line CL, and a stacked layer body of the insulating layers 111, 112, 113, and 114 and the organic insulating layer 12 is formed on the substrate 10.

This configuration example also prevents the cutter from contacting the surrounding partition 7 when the mother substrate 100 is separated. Thus, the configuration example achieves the same effects as those of the configuration example shown in FIG. 7A.

Further, the inorganic insulating layer 5, the sealing layer SE3, and the sealing layer SE2 are absent on the organic insulating layer 12 at the cutting line CL. Thus, when the mother substrate 100 is separated, the configuration can prevent a defect in which fragments of the inorganic insulating layer 5, the sealing layer SE3, and the sealing layer SE2 become foreign matter. Thus, the configuration can suppress a decrease in manufacturing yield.

FIG. 15B is a schematic cross-sectional view showing the outermost peripheral portion PP of the display panel PNL separated along the cutting line CL shown in FIG. 15A.

The organic insulating layer 12 has the end portion 12E directly above the substrate edge 10E. The inorganic insulating layer 5 is not provided directly above the substrate edge 10E and has the end portion E11 between the outermost surrounding partition 7 and the substrate edge 10E. The sealing layer SE3 is provided on the inorganic insulating layer 5, is not provided directly above the substrate edge 10E, and has the end portion E13 between the outermost surrounding partition 7 and the substrate edge 10E. In the illustrated example, the end portion E13 is located on the end portion E11. The sealing layer SE2 is provided on the sealing layer SE3, is not provided directly above the substrate edge 10E, and has the end portion E12 between the outermost surrounding partition 7 and the substrate edge 10E. In the illustrated example, the end portion E12 is located on the end portion E13.

The following will describe examples of layouts of the surrounding partitions 7 provided in the area including the cutting line CL of the mother substrate 100.

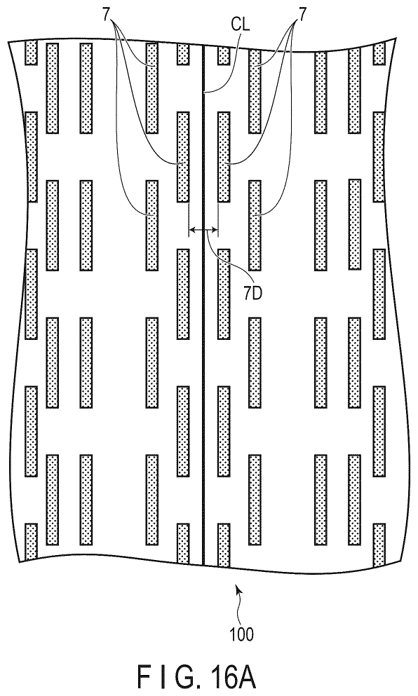

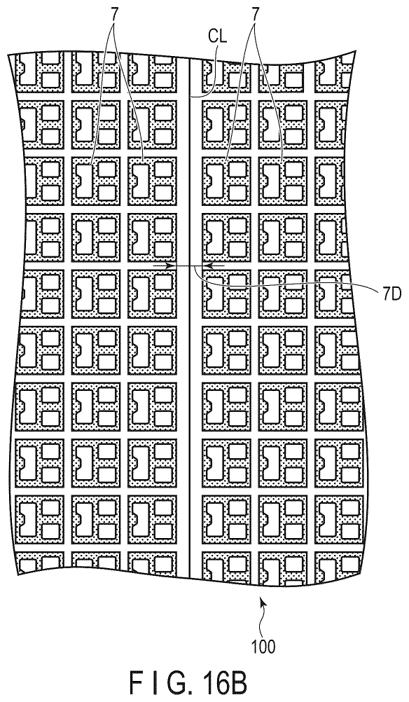

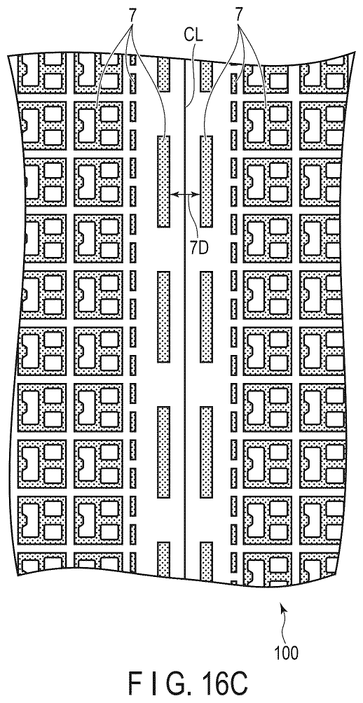

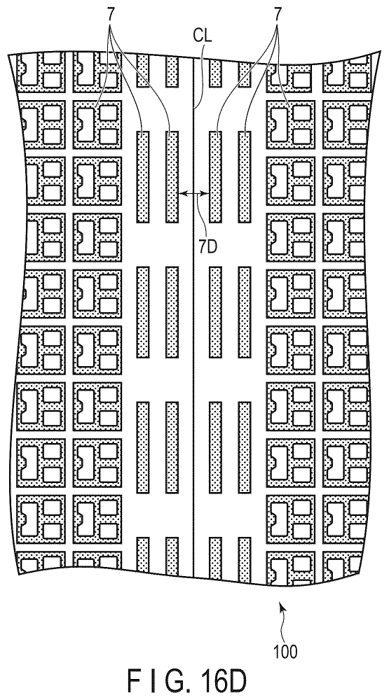

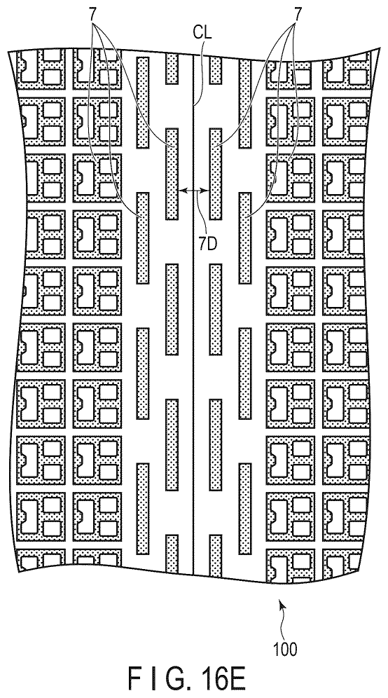

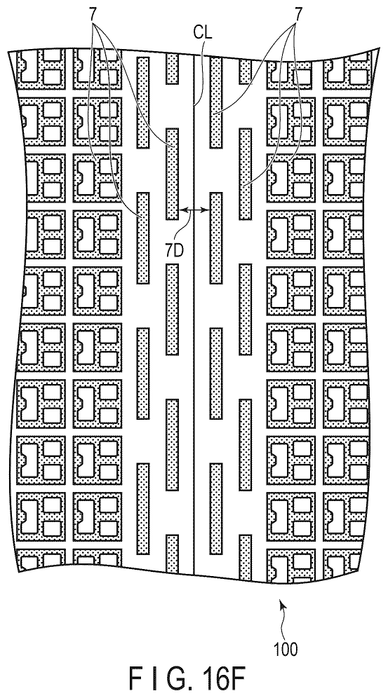

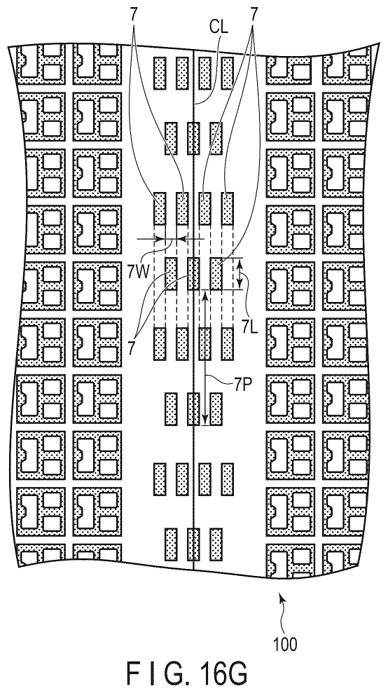

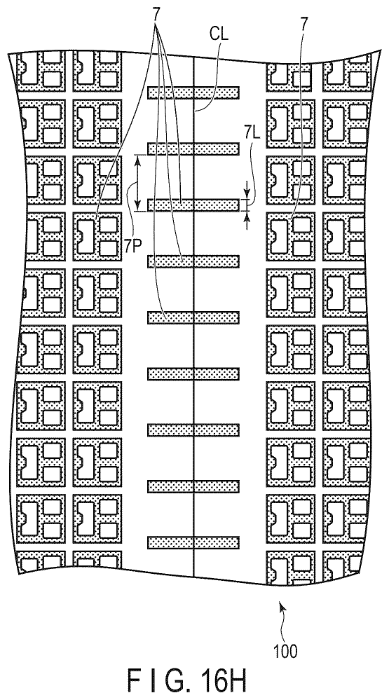

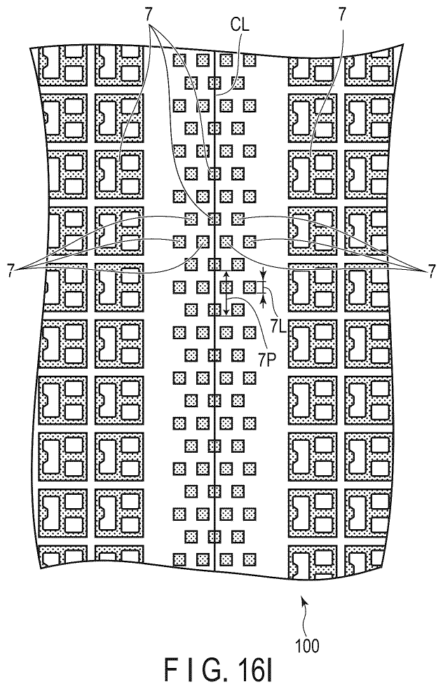

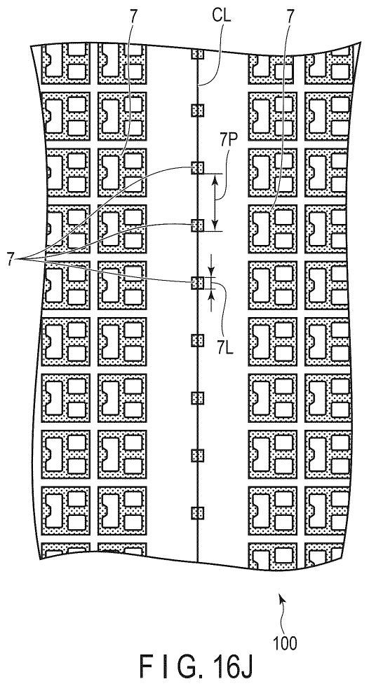

FIG. 16A is a plan view showing an example of the layout of the surrounding partitions 7.

Each of the surrounding partitions 7 is formed in a rectangular shape extending along the cutting line CL in plan view. An interval 7D between the surrounding partitions 7 adjacent across the cutting line CL is set to, for example, 50 μm.

For example, in the left-side area with respect to the cutting line CL, the plurality of surrounding partitions 7 close to the cutting line CL are arranged in a staggered pattern. The plurality of surrounding partitions 7 located in the right-side area with respect to the cutting line CL are arranged line-symmetrically with the plurality of surrounding partitions 7 located in the left-side area with respect to the cutting line CL.

FIG. 16B is a plan view showing another example of the layout of the surrounding partitions 7.

Each of the surrounding partition 7 is formed in a grating shape in plan view. In one example, the surrounding partitions 7 are formed in the same patters as the lattice-shaped partitions 6 shown in FIG. 2.

The plurality of surrounding partitions 7 located in the left-side area with respect to the cutting line CL are arranged in the same manner as the plurality of surrounding partitions 7 located in the right-side area with respect to the cutting line CL. The surrounding partitions 7 that are adjacent across the cutting line CL are arranged with the interval 7D. In each of the left-side area and the right-side area, the plurality of surrounding partitions 7 are arranged at an interval smaller than the interval 7D.

FIG. 16C is a plan view showing another example of the layout of the surrounding partitions 7.

For example, in the left-side area with respect to the cutting line CL, the surrounding partitions 7 having a rectangular shape are provided in the vicinity of the cutting line CL, the surrounding partitions 7 having a lattice shape are provided at positions away from the cutting line CL, and the surrounding partitions 7 having a dashed-line shape are provided between the rectangular surrounding partitions 7 and the lattice-shaped surrounding partitions 7.

The plurality of surrounding partitions 7 located in the left-side area with respect to the cutting line CL are arranged in the same manner as the plurality of surrounding partitions 7 located in the right-side area with respect to the cutting line CL. The surrounding partitions 7 that are adjacent across the cutting line CL are arranged with the interval 7D.

FIG. 16D is a plan view showing another example of the layout of the surrounding partitions 7.

For example, in the left-side area with respect to the cutting line CL, the rectangular surrounding partitions 7 are provided in two rows in the vicinity of the cutting line CL, and the lattice-shaped surrounding partitions 7 are provided at positions away from the cutting line CL.

The plurality of surrounding partitions 7 located in the left-side area with respect to the cutting line CL are arranged in the same manner as the plurality of surrounding partitions 7 located in the right-side area with respect to the cutting line CL. The surrounding partitions 7 that are adjacent across the cutting line CL are arranged with the interval 7D.

FIG. 16E is a plan view showing another example of the layout of the surrounding partitions 7.

For example, in the left-side area with respect to the cutting line CL, the rectangular surrounding partitions 7 are provided in the staggered pattern in the vicinity of the cutting line CL, and the lattice-shaped surrounding partitions 7 are provided at positions away from the cutting line CL.

The plurality of surrounding partitions 7 located in the left-side area with respect to the cutting line CL are arranged in the same manner as the plurality of surrounding partitions 7 located in the right-side area with respect to the cutting line CL. The surrounding partitions 7 that are adjacent across the cutting line CL are arranged with the interval 7D.

FIG. 16F is a plan view showing another example of the layout of the surrounding partitions 7.

For example, in the left-side area with respect to the cutting line CL, the rectangular surrounding partitions 7 are provided in the staggered pattern in the vicinity of the cutting line CL, and the lattice-shaped surrounding partitions 7 are provided at positions away from the cutting line CL.

The plurality of surrounding partitions 7 located in the left-side area with respect to the cutting line CL are arranged in the same manner as the plurality of surrounding partitions 7 located in the right-side area with respect to the cutting line CL. The surrounding partitions 7 that are adjacent across the cutting line CL are arranged in a staggered pattern with the interval 7D.

In the layouts shown in FIG. 16A to FIG. 16F, the surrounding partitions 7 are absent at the cutting line CL. Thus, when the mother substrate 100 is separated, the frequency with which the cutter contacts the surrounding partitions 7 is extremely low. Thus, damage to the cutter blade can be reduced.

FIG. 16G is a plan view showing another example of the layout of the surrounding partitions 7.

For example, in the left-side area with respect to the cutting line CL, three rows of dashed-line surrounding partitions 7 are provided in the vicinity of the cutting line CL. An interval between the surrounding partitions 7 that are arranged in the three rows is equal to a width 7W of one surrounding partition 7.

The plurality of surrounding partitions 7 located in the left-side area with respect to the cutting line CL are arranged in the same manner as the plurality of surrounding partitions 7 located in the right-side area with respect to the cutting line CL.

At the position overlapping the cutting line CL, the plurality of dashed-line surrounding partitions 7 are provided. A length 7L of the long side of each surrounding partition 7 is smaller than a pitch 7P of the surrounding partitions 7 along the cutting line CL.

FIG. 16H is a plan view showing another example of the layout of the surrounding partitions 7.

At the position overlapping the cutting line CL, the plurality of surrounding partitions 7 are provided. Each of these surrounding partitions 7 is formed in a rectangular shape extending to intersect the cutting line CL. The length 7L of the short side of each surrounding partition 7 is smaller than the pitch 7P of the surrounding partitions 7 along the cutting line CL.

FIG. 16I is a plan view showing another example of the layout of the surrounding partitions 7.

For example, in the left-side area with respect to the cutting line CL, three rows of dot-shaped surrounding partitions 7 are provided in the vicinity of the cutting line CL.

The plurality of surrounding partitions 7 located in the left-side area with respect to the cutting line CL are arranged in the same manner as the plurality of surrounding partitions 7 located in the right-side area with respect to the cutting line CL.

At the position overlapping the cutting line CL, the plurality of dot-shaped surrounding partitions 7 are provided. The length 7L of the surrounding partition 7 is smaller than the pitch 7P of the surrounding partition 7 along the cutting line CL.

FIG. 16J is a plan view showing another example of the layout of the surrounding partitions 7.

At the position overlapping the cutting line CL, the plurality of dot-shaped surrounding partitions 7 are provided in one row. These surrounding partitions 7 are dot-shaped. The length 7L of the surrounding partition 7 is smaller than the pitch 7P of the surrounding partition 7 along the cutting line CL.

@Further, the lattice-shaped surrounding partitions 7 are provided at positions away from the cutting line CL. No other peripheral partitions are provided between the dot-shaped surrounding partitions 7 and the lattice-shaped surrounding partitions 7.

In the layouts shown in FIG. 16G to FIG. 16J, the plurality of surrounding partitions 7 are provided at the cutting line CL at the constant pitch 7P. Thus, when the mother substrate 100 is separated, the cutter contacts the surrounding partitions 7 at a constant frequency. In particular, in the layouts shown in FIG. 16G to FIG. 16I, even when the cutter is slightly deviated from the cutting line CL, the cutter contacts the surrounding partitions 7 at a constant frequency. Thus, variations in the service life of the cutter blade can be suppressed.

In the above embodiments, for example, the sealing layers SE1, SE11, SE12, and SE13 correspond to the first sealing layer, the resin layer RS1 corresponds to the first resin layer, the sealing layer SE2 corresponds to the second sealing layer, the resin layer RS2 corresponds to the second resin layer, and the sealing layer SE3 corresponds to the third sealing layer.

Further, the aperture OP11 corresponds to the first aperture, the aperture OP12 corresponds to the second aperture, the aperture OP13 corresponds to the third aperture, the end portion E11 corresponds to the first end portion, the end portion E12 corresponds to the second end portion, and the end portion E13 corresponds to the third end portion.

As described above, the present embodiment can provide the mother substrate and the display device each capable of suppressing an increase in manufacturing cost.

All of the mother substrates and the display devices that can be implemented by a person of ordinary skill in the art through arbitrary design changes to the mother substrates and the display devices described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A mother substrate comprising:
a substrate;
an organic insulating layer provided above the substrate across a display area configured to display an image and a surrounding area outside the display area;
an inorganic insulating layer provided on the organic insulating layer across the display area and the surrounding area;
a lower electrode provided on the organic insulating layer in the display area and having a peripheral portion covered by the inorganic insulating layer;
a stacked film provided on the lower electrode and including an upper electrode and an organic layer including a light-emitting layer;
a partition provided on the inorganic insulating layer in the display area, having conductivity, contacting the upper electrode, and formed in an overhang shape;
a first sealing layer formed of an inorganic insulating material and provided on the stacked film in the display area;
a first resin layer provided above the first sealing layer in the display area;
a second sealing layer formed of an inorganic insulating material, provided on the first resin layer in the display area, and provided in the surrounding area; and
a surrounding partition provided between the inorganic insulating layer and the second sealing layer in the surrounding area and formed in an overhang shape.

2. The mother substrate of claim 1, wherein
the organic insulating layer is provided at a cutting line.

3. The mother substrate of claim 2, wherein
the inorganic insulating layer is provided on the organic insulating layer at the cutting line, and
the second sealing layer is provided on the inorganic insulating layer at the cutting line.

4. The mother substrate of claim 2, wherein
the inorganic insulating layer has a first aperture overlapping the cutting line, and
the second sealing layer is provided on the inorganic insulating layer and is provided on the organic insulating layer through the first aperture at the cutting line.

5. The mother substrate of claim 2, wherein
the inorganic insulating layer is provided on the organic insulating layer at the cutting line, and
the second sealing layer is provided on the inorganic insulating layer and has a second aperture overlapping the cutting line.

6. The mother substrate of claim 2, wherein
the inorganic insulating layer has a first aperture overlapping the cutting line, and
the second sealing layer is provided on the inorganic insulating layer and has a second aperture overlapping the first aperture at the cutting line.

7. The mother substrate of claim 2, further comprising:
a third sealing layer formed of an inorganic insulating material and provided between the surrounding partition and the second sealing layer in the surrounding area.

8. The mother substrate of claim 7, wherein
the inorganic insulating layer is provided on the organic insulating layer at the cutting line,
the third sealing layer is provided on the inorganic insulating layer at the cutting line, and
the second sealing layer is provided on the third sealing layer at the cutting line.

9. The mother substrate of claim 7, wherein
the inorganic insulating layer has a first aperture overlapping the cutting line,
the third sealing layer is provided on the inorganic insulating layer and is provided on the organic insulating layer through the first aperture at the cutting line, and
the second sealing layer is provided on the third sealing layer at the cutting line.

10. The mother substrate of claim 7, wherein
the inorganic insulating layer is provided on the organic insulating layer at the cutting line,
the third sealing layer is provided on the inorganic insulating layer and has a third aperture overlapping the cutting line, and
the second sealing layer is provided on the third sealing layer and has a second aperture overlapping the third aperture at the cutting line.

11. A display device comprising:
a substrate having a substrate edge;
an organic insulating layer provided above the substrate across a display area configured to display an image and a surrounding area outside the display area, the organic insulating layer having an end portion directly above the substrate edge;
an inorganic insulating layer provided on the organic insulating layer across the display area and the surrounding area;
a lower electrode provided on the organic insulating layer in the display area and having a peripheral portion covered by the inorganic insulating layer;
a stacked film provided on the lower electrode and including an upper electrode and an organic layer including a light-emitting layer;
a partition provided on the inorganic insulating layer in the display area, having conductivity, contacting the upper electrode, and formed in an overhang shape;
a first sealing layer formed of an inorganic insulating material and provided on the stacked film in the display area;
a first resin layer provided above the first sealing layer in the display area and having an end portion between the substrate edge and the display area;
a second sealing layer formed of an inorganic insulating material, provided on the first resin layer in the display area, and provided in the surrounding area; and
a surrounding partition provided between the inorganic insulating layer and the second sealing layer in the surrounding area and formed in an overhang shape.

12. The display device of claim 11, wherein
the inorganic insulating layer has a first end portion provided on the organic insulating layer directly above the substrate edge, and
the second sealing layer has a second end portion provided on the inorganic insulating layer directly above the substrate edge.

13. The display device of claim 11, wherein
the inorganic insulating layer is not provided directly above the substrate edge and has a first end portion between the substrate edge and the surrounding partition, and
the second sealing layer covers the first end portion and has a second end portion provided on the organic insulating layer directly above the substrate edge.

14. The display device of claim 11, wherein
the inorganic insulating layer has a first end portion provided on the organic insulating layer directly above the substrate edge, and
the second sealing layer is provided on the inorganic insulating layer, is not provided directly above the substrate edge, and has a second end portion between the substrate edge and the surrounding partition.

15. The display device of claim 11, wherein
the inorganic insulating layer is not provided directly above the substrate edge and has a first end portion between the substrate edge and the surrounding partition, and
the second sealing layer is provided on the inorganic insulating layer, is not provided directly above the substrate edge, and has a second end portion between the substrate edge and the surrounding partition.

16. The display device of claim 11, further comprising:
a third sealing layer formed of an inorganic insulating material and provided between the surrounding partition and the second sealing layer in the surrounding area.

17. The display device of claim 16, wherein
the inorganic insulating layer has a first end portion provided on the organic insulating layer directly above the substrate edge,
the third sealing layer has a third end portion provided on the inorganic insulating layer directly above the substrate edge, and
the second sealing layer has a second end portion provided on the third sealing layer directly above the substrate edge.

18. The display device of claim 16, wherein
the inorganic insulating layer is not provided directly above the substrate edge and has a first end portion between the substrate edge and the surrounding partition,
the third sealing layer covers the first end portion and has a third end portion provided on the organic insulating layer directly above the substrate edge, and
the second sealing layer has a second end portion provided on the third sealing layer directly above the substrate edge.

19. The display device of claim 16, wherein
the inorganic insulating layer has a first end portion provided on the organic insulating layer directly above the substrate edge,
the third sealing layer is provided on the inorganic insulating layer, is not provided directly above the substrate edge, and has a third end portion between the substrate edge and the surrounding partition, and
the second sealing layer is provided on the third sealing layer, is not provided directly above the substrate edge, and has a second end portion between the substrate edge and the surrounding partition.

20. The display device of claim 16, wherein
the inorganic insulating layer is not provided directly above the substrate edge and has a first end portion between the substrate edge and the surrounding partition,
the third sealing layer is not provided directly above the substrate edge and has a third end portion between the substrate edge and the surrounding partition, and
the second sealing layer is not provided directly above the substrate edge and has a second end portion between the substrate edge and the surrounding partition.
